(19) United States
(12) Patent Application Publication
(10) Pub. No.: US 2024/0348013 A1
(43) Pub. Date: Oct. 17, 2024

(54) SURFACE EMITTING LASER ELEMENT AND LIGHT SOURCE DEVICE

(71) Applicant: SONY GROUP CORPORATION, Tokyo (JP)

(72) Inventor: Hideki WATANABE, Tokyo (JP)

(21) Appl. No.: 18/294,915

(22) PCT Filed: Feb. 18, 2022
(86) PCT No.: PCT/JP2022/006542

§ 371 Date: Feb. 2, 2024

(30) Foreign Application Priority Data
Sep. 17, 2021 (JP) 2021-152337

(51) Int. Cl. H01S 5/183; H01S 5/30

(52) U.S. Cl. CPC H01S 5/18311; H01S 5/18369; H01S 5/3009

(57) ABSTRACT

Provided is a surface emitting laser element capable of suppressing an increase in driving voltage for switching a surface emitting laser regardless of the size of a light emitting region.

The present technology provides a surface emitting laser element including: a first structure including a first multilayer film reflector; a second structure including a second multilayer film reflector; and a resonator disposed between the first and second structures, in which the resonator includes an active layer in which at least a light emitting region is disposed between the first and second multilayer film reflectors, and the second structure is provided with a field effect transistor that controls injection of a current into the light emitting region. According to the surface emitting laser element according to the present technology, it is possible to provide the surface emitting laser element capable of suppressing an increase in voltage driving voltage for switching the surface emitting laser regardless of the size of the light emitting region.

### TECHNICAL FIELD

The technology according to the present disclosure (hereinafter also referred to as “the present technology”) relates to a surface emitting laser element and a light source device.

### BACKGROUND ART

Conventionally, a surface emitting laser element having a bipolar transistor for controlling a current injected into a light emitting region is known (see, for example, Patent Document 1).

### CITATION LIST

### Patent Document

Patent Document 1: Japanese Unexamined Patent Application Publication No. 2017-532783

### SUMMARY OF THE INVENTION

### Problems to be Solved by the Invention

However, in the conventional surface emitting laser element, there is room for improvement in suppressing an increase in voltage for switching the surface emitting laser regardless of the size of the light emitting region.

Therefore, a main object of the present technology is to provide a surface emitting laser element capable of suppressing an increase in voltage for switching the surface emitting laser regardless of the size of the light emitting region.

### Solutions to Problems

The present technology provides a surface emitting laser element including:
a first structure including a first multilayer film reflector;
a second structure including a second multilayer film reflector; and
a resonator disposed between the first and second structures,
in which the resonator includes an active layer in which at least a light emitting region is disposed between the first and second multilayer film reflectors, and
the second structure is provided with a field effect transistor that controls injection of a current into the light emitting region.

The field effect transistor may include: a drain region provided at a position of the second structure corresponding to the light emitting region; and a source region of the second structure provided around the drain region.

An electrical resistance between the source region and the first multilayer film reflector may be larger than an electrical resistance between the drain region and the first multilayer film reflector.

The source region may surround the drain region.

The field effect transistor may include: a gate electrode provided at a position of the second structure corresponding to the drain region and the source region; and a gate insulating film provided between the gate electrode and the drain region and the source region.

The field effect transistor may include: a source electrode provided at a position of the second structure in contact with the source region; and a drain electrode provided in the first structure.

The drain region and the source region may be provided at a position of the second structure on a side opposite to a side of the active layer of the second multilayer film reflector.

The second structure may further include a semiconductor layer disposed on a surface of the second multilayer film reflector on a side opposite to the side of the active layer, and the semiconductor layer may include: a first impurity region as the drain region; a second impurity region as the source region; and a semiconductor region having a conductivity type different from a conductivity type of the drain region and the source region, at least a part of the semiconductor region being disposed between the first and second impurity regions.

The drain region may be in contact with the second multilayer film reflector, and the source region may not be in contact with the second multilayer film reflector.

At least the drain region of the drain region and the source region may be provided in the second multilayer film reflector.

The drain region and the source region may be provided in the second multilayer film reflector, and an ion implantation region may be provided between the drain region and the source region in the second multilayer film reflector.

The ion implantation region may be provided in an entire region in a thickness direction of the second multilayer film reflector.

The second structure may further include a semiconductor layer disposed between the second multilayer film reflector and the resonator, the drain region may be a region corresponding to the light emitting region of the semiconductor layer, and the source region may be a region around the drain region of the semiconductor layer.

An ion implantation region may be provided between the drain region and the source region in the semiconductor layer.

The ion implantation region may be provided in an entire region in a thickness direction of the semiconductor layer.

The semiconductor layer may include: a first impurity region as the drain region; a second impurity region as the source region; and a semiconductor region having a conductivity type different from a conductivity type of the drain region and the source region, at least a part of the semiconductor region being disposed between the first and second impurity regions.

The second structure may further include a transparent conductive film in which a part corresponding to the light emitting region is disposed between the second multilayer film reflector and the semiconductor layer and an other part is exposed.

The second structure may further include a semiconductor layer disposed on a side opposite to a side of the first multilayer film reflector of the resonator and around the second multilayer film reflector, the drain region may be at least a part of the second multilayer film reflector, and the semiconductor layer may include: an impurity region as the source region; and a semiconductor region having a conductivity type different from a conductivity type of the drain region and the source region, at least a part of the semiconductor region being disposed between the source region and the drain region.

At least one of the resonator, the first multilayer film reflector, or the second multilayer film reflector may be provided with a carrier confinement portion.

The present technology also provides a light source device including:
the surface emitting laser element,
a first power supply that generates a current to be injected into a light emitting region of the surface emitting laser element; and
a second power supply that drives a field effect transistor of the surface emitting laser element.

### BRIEF DESCRIPTION OF DRAWINGS

FIG. 1A is a plan view of a surface emitting laser element according to a first embodiment of the present technology. FIG. 1B is a cross-sectional view of the surface emitting laser element according to the first embodiment of the present technology.

FIG. 2 is a diagram illustrating a standby state of the surface emitting laser element illustrated in FIG. 1B.

FIG. 3 is a diagram illustrating a state at the time of driving the surface emitting laser element illustrated in FIG. 1B.

FIG. 4 is a flowchart for explaining a method for manufacturing the surface emitting laser element illustrated in FIG. 1B.

FIGS. 5A and 5B are cross-sectional views (Part 1 and Part 2) for explaining the method for manufacturing the surface emitting laser element illustrated in FIG. 1B.

FIGS. 6A and 6B are cross-sectional views (Part 3 and Part 4) for explaining the method for manufacturing the surface emitting laser element illustrated in FIG. 1B.

FIGS. 7A and 7B are cross-sectional views (Part 5 and Part 6) for explaining the method for manufacturing the surface emitting laser element illustrated in FIG. 1B.

FIGS. 8A and 8B are cross-sectional views (Part 7 and Part 8) for explaining the method for manufacturing the surface emitting laser element illustrated in FIG. 1B.

FIGS. 9A and 9B are cross-sectional views (Part 9 and Part 10) for explaining the method for manufacturing the surface emitting laser element illustrated in FIG. 1B.

FIGS. 10A and 10B are cross-sectional views (Part 11 and Part 12) for explaining the method for manufacturing the surface emitting laser element illustrated in FIG. 1B.

FIGS. 11A and 11B are cross-sectional views (Part 13 and Part 14) for explaining the method for manufacturing the surface emitting laser element illustrated in FIG. 1B.

FIGS. 12A and 12B are cross-sectional views (Part 15 and Part 16) for explaining the method for manufacturing the surface emitting laser element illustrated in FIG. 1B.

FIGS. 13A and 13B are cross-sectional views (Part 17 and Part 18) for explaining the method for manufacturing the surface emitting laser element illustrated in FIG. 1B.

FIG. 14A is a plan view of a surface emitting laser element according to a second embodiment of the present technology. FIG. 14B is a cross-sectional view of the surface emitting laser element according to the second embodiment of the present technology.

FIG. 15 is a flowchart for explaining a method for manufacturing the surface emitting laser element illustrated in FIG. 14B.

FIGS. 16A and 16B are cross-sectional views (Part 1 and Part 2) for explaining the method for manufacturing the surface emitting laser element illustrated in FIG. 14B.

FIGS. 17A and 17B are cross-sectional views (Part 3 and Part 4) for explaining the method for manufacturing the surface emitting laser element illustrated in FIG. 14B.

FIGS. 18A and 18B are cross-sectional views (Part 5 and Part 6) for explaining the method for manufacturing the surface emitting laser element illustrated in FIG. 14B.

FIGS. 19A and 19B are cross-sectional views (part 7 and part 8) for explaining the method for manufacturing the surface emitting laser element illustrated in FIG. 14B.

FIGS. 20A and 20B are cross-sectional views (Part 9 and Part 10) for explaining the method for manufacturing the surface emitting laser element illustrated in FIG. 14B.

FIGS. 21A and 21B are cross-sectional views (Part 11 and Part 12) for explaining the method for manufacturing the surface emitting laser element illustrated in FIG. 14B.

FIGS. 22A and 22B are cross-sectional views (Part 13 and Part 14) for explaining the method for manufacturing the surface emitting laser element illustrated in FIG. 14B.

FIG. 23 is a cross-sectional view (Part 15) for explaining the method for manufacturing the surface emitting laser element illustrated in FIG. 1B.

FIG. 24A is a plan view of a surface emitting laser element according to a third embodiment of the present technology. FIG. 24B is a cross-sectional view of the surface emitting laser element according to the third embodiment of the present technology.

FIG. 25 is a flowchart for explaining a method for manufacturing the surface emitting laser element illustrated in FIG. 24B.

FIGS. 26A and 26B are cross-sectional views (Part 1 and Part 2) for explaining the method for manufacturing the surface emitting laser element illustrated in FIG. 24B.

FIGS. 27A and 27B are cross-sectional views (Part 3 and Part 4) for explaining the method for manufacturing the surface emitting laser element illustrated in FIG. 24B.

FIGS. 28A and 28B are cross-sectional views (Part 5 and Part 6) for explaining the method for manufacturing the surface emitting laser element illustrated in FIG. 24B.

FIGS. 29A and 29B are cross-sectional views (part 7 and part 8) for explaining the method for manufacturing the surface emitting laser element illustrated in FIG. 24B.

FIGS. 30A and 30B are cross-sectional views (Part 9 and Part 10) for explaining the method for manufacturing the surface emitting laser element illustrated in FIG. 24B.

FIGS. 31A and 31B are cross-sectional views (Part 11 and Part 12) for explaining the method for manufacturing the surface emitting laser element illustrated in FIG. 24B.

FIGS. 32A and 32B are cross-sectional views (Part 13 and Part 14) for explaining the method for manufacturing the surface emitting laser element illustrated in FIG. 24B.

FIGS. 33A and 33B are cross-sectional views (Part 15 and Part 16) for explaining the method for manufacturing the surface emitting laser element illustrated in FIG. 24B.

FIG. 34A is a cross-sectional view of a surface emitting laser element according to Modification 1 of the first embodiment of the present technology. FIG. 34B is a cross-sectional view of a surface emitting laser element according to Modification 2 of the first embodiment of the present technology.

FIG. 35A is a cross-sectional view of a surface emitting laser element according to Modification 3 of the first embodiment of the present technology. FIG. 35B is a cross-sectional view of a surface emitting laser element according to Modification 4 of the first embodiment of the present technology.

FIG. 36A is a cross-sectional view of a surface emitting laser element according to Modification 5 of the first embodiment of the present technology. FIG. 36B is a cross-sectional view of a surface emitting laser element according to Modification 6 of the first embodiment of the present technology.

FIG. 37A is a cross-sectional view of a surface emitting laser element according to Modification 7 of the first embodiment of the present technology. FIG. 37B is a cross-sectional view of a surface emitting laser element according to Modification 8 of the first embodiment of the present technology.

FIG. 38A is a cross-sectional view of a surface emitting laser element according to Modification 1 of the second embodiment of the present technology. FIG. 38B is a cross-sectional view of a surface emitting laser element according to Modification 2 of the second embodiment of the present technology.

FIG. 39A is a cross-sectional view of a surface emitting laser element according to Modification 3 of the second embodiment of the present technology. FIG. 39B is a cross-sectional view of a surface emitting laser element according to Modification 4 of the second embodiment of the present technology.

FIG. 40A is a cross-sectional view of a surface emitting laser element according to Modification 5 of the second embodiment of the present technology. FIG. 40B is a cross-sectional view of a surface emitting laser element according to Modification 6 of the second embodiment of the present technology.

FIG. 41A is a cross-sectional view of a surface emitting laser element according to Modification 7 of the second embodiment of the present technology. FIG. 41B is a cross-sectional view of a surface emitting laser element according to Modification 8 of the second embodiment of the present technology.

FIG. 42A is a cross-sectional view of a surface emitting laser element according to Modification 9 of the second embodiment of the present technology. FIG. 42B is a cross-sectional view of a surface emitting laser element according to Modification 10 of the second embodiment of the present technology.

FIG. 43A is a cross-sectional view of a surface emitting laser element according to Modification 1 of the third embodiment of the present technology. FIG. 43B is a cross-sectional view of a surface emitting laser element according to Modification 2 of the third embodiment of the present technology.

FIGS. 44A and 44B are circuit block diagrams illustrating an example of a configuration and a function of a light source device.

FIG. 45 is a diagram illustrating an application example of the surface emitting laser element according to the first embodiment of the present technology to a distance measuring device.

FIG. 46 is a block diagram illustrating an example of a schematic configuration of a vehicle control system.

FIG. 47 is an explanatory diagram illustrating an example of installation positions of a distance measuring device.

### MODE FOR CARRYING OUT THE INVENTION

Hereinafter, preferred embodiments of the present technology will be described in detail with reference to the accompanying drawings. Note that in the present specification and the drawings, components having substantially the same functional configurations are denoted by the same reference signs, and redundant descriptions are omitted. The embodiments described below illustrate representative embodiments of the present technology, and the scope of the present technology is not narrowly interpreted by these embodiments. In the present specification, even in a case where it is described that each of the surface emitting laser element and the light source device according to the present technology exhibits a plurality of effects, each of the surface emitting laser element and the light source device according to the present technology is only required to exhibit at least one effect. The effects described herein are merely examples and are not limited, and other effects may be provided.

Furthermore, the description will be given in the following order.
1. Introduction
2. Surface Emitting Laser Element According to First Embodiment of Present Technology
(1) Configuration of Surface Emitting Laser Element
(2) Operation of Surface Emitting Laser Element
(3) Method for Manufacturing Surface Emitting Laser Element
(4) Effects of Surface Emitting Laser Element and Method for Manufacturing Surface Emitting Laser Element
3. Surface Emitting Laser Element According to Second Embodiment of Present Technology
(1) Configuration of Surface Emitting Laser Element
(2) Operation of Surface Emitting Laser Element
(3) Method for Manufacturing Surface Emitting Laser Element
(4) Effects of Surface Emitting Laser Element and Method for Manufacturing Surface Emitting Laser Element
4. Surface Emitting Laser Element According to Third Embodiment of Present Technology
(1) Configuration of Surface Emitting Laser Element
(2) Operation of Surface Emitting Laser Element
(3) Method for Manufacturing Surface Emitting Laser Element
(4) Effects of Surface Emitting Laser Element and Method for Manufacturing Surface Emitting Laser Element
5. Surface Emitting Laser Element According to Modifications 1 to 8 of First Embodiment of Present Technology
6. Surface Emitting Laser Element According to Modifications 1 to 10 of Second Embodiment of Present Technology
7. Surface Emitting Laser Element According to Modifications 1 and 2 of Third Embodiment of Present Technology
8. Light Source Device Including Surface Emitting Laser Element According to Present Technology
9. Other Modifications of Present Technology
10. Application Example to Electronic Device
11. Example in Which Surface Emitting Laser Element Is Applied to Distance Measuring Device
12. Example in Which Distance Measuring Device Is Mounted on Moving Body

### <1. Introduction>

Conventionally, a surface emitting laser element in which a vertical cavity surface emitting laser (VCSEL) and a laser driver having a bipolar transistor for controlling ON/OFF of oscillation of the VCSEL are integrated is known (see, for example, Patent Document 1). However, in a laser driver having a bipolar transistor, switching is performed by applying/releasing the current injected into the light emitting region of the VCSEL, and thus there is a problem that the smaller the light emitting area (the size of the light emitting region) of the VCSEL (the larger the series resistance of the VCSEL), the higher the voltage for switching the surface emitting laser.

Therefore, in view of such a problem, the inventor has developed a surface emitting laser element in which a VCSEL and a laser driver having a field effect transistor (FET) which is a unipolar transistor are integrated. According to this surface emitting laser element, since the laser driver switches the VCSEL by applying/releasing the voltage, the voltage for switching the surface emitting laser does not depend on the light emitting area. Supplementarily, in the field effect transistor, since the switching of the current to the light emitting region only controls the carrier density of the surface by the gate voltage like, for example, the MOSFET, the voltage for switching the surface emitting laser does not depend on the light emitting area.

As a result, according to the surface emitting laser element, it is possible to provide the surface emitting laser element capable of suppressing an increase in voltage for switching the surface emitting laser regardless of the size of the light emitting region.

### <2. Surface Emitting Laser Element According to First Embodiment of Present Technology>

### (1) Configuration of Surface Emitting Laser Element

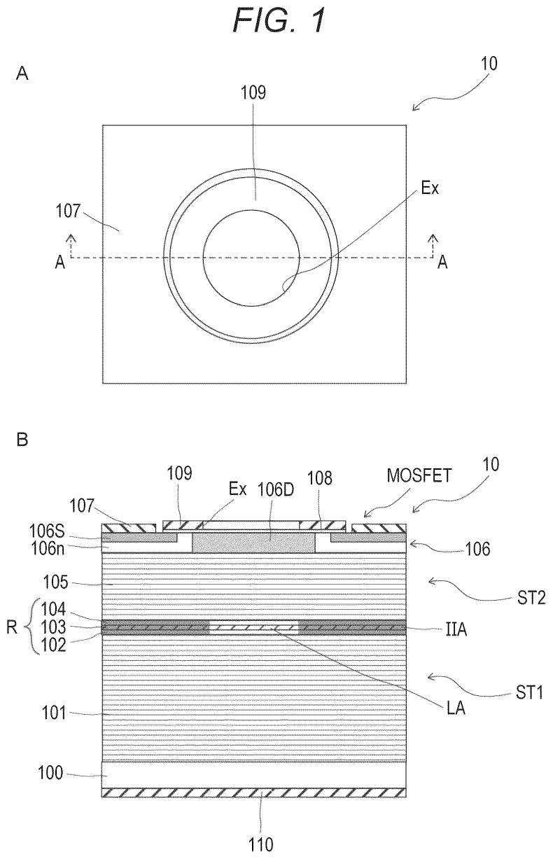

Hereinafter, a configuration of a surface emitting laser element according to a first embodiment of the present technology will be described with reference to FIGS. 1A and 1B. FIG. 1A is a plan view of a surface emitting laser element according to the first embodiment of the present technology. FIG. 1B is a cross-sectional view of the surface emitting laser element according to the first embodiment of the present technology. More specifically, FIG. 1B is a cross-sectional view taken along line A-A of FIG. 1A. Hereinafter, in the cross-sectional view of FIG. 1B and the like, the upper side will be described as “upper” and the lower side will be described as “lower” for convenience.

The surface emitting laser element 10 according to the first embodiment can include only a single surface emitting laser element 10, or can include a surface emitting laser array in which a plurality of surface emitting laser elements 10 is arranged in an array.

As an example, as illustrated in FIG. 1B, the surface emitting laser element 10 according to the first embodiment includes a first structure ST1 including a first multilayer film reflector 101, a second structure ST2 including a second multilayer film reflector 105, and a resonator R arranged between the first and second structures ST1 and ST2.

The first structure ST1 includes a substrate 100 and a first electrode 110 in addition to the first multilayer film reflector 101. The first multilayer film reflector 101 is provided on the upper surface (front surface) of the substrate 100. The first electrode 110 is provided on the lower surface (back surface) of the substrate 100.

The resonator R includes an active layer 103 in which at least the light emitting region LA (for example, the entire region) is disposed between the first and second multilayer film reflectors 101 and 105. The resonator R further includes first and second cladding layers 102 and 104 disposed at positions vertically sandwiching the active layer 103. The first cladding layer 102 is provided on the lower side (substrate 100 side) of the second cladding layer 104.

The second structure ST2 is provided with a field effect transistor (FET) that controls injection of current into the light emitting region LA. The field effect transistor is also called a unipolar transistor. The field effect transistor has a function of switching on/off of energization to the light emitting region LA. Here, a metal oxide semiconductor field effect transistor (MOSFET) is used as the field effect transistor.

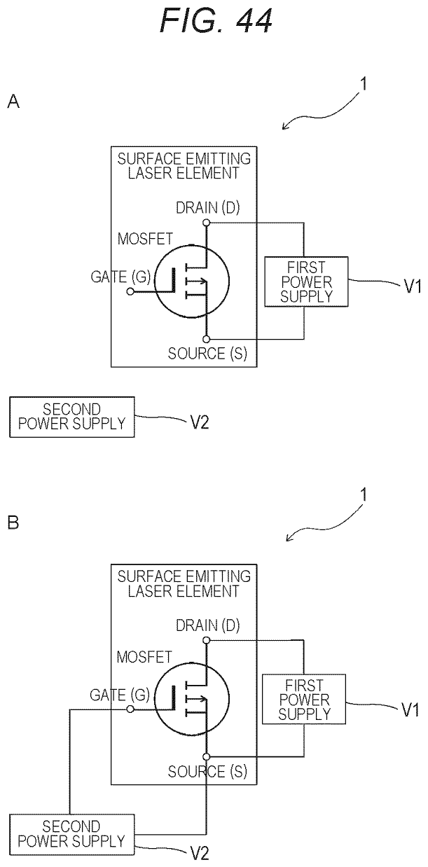

The MOSFET constitutes a part of the laser driver. In addition to the MOSFET, the laser driver includes a first power supply V1 for generating a current injected into the light emitting region LA and a second power supply V2 for driving the MOSFET (see FIGS. 44A and 44B).

### (Substrate)

The substrate 100 is, for example, a GaAs substrate of a first conductivity type (for example, n-type).

### (First Electrode)

As an example, the first electrode 110 (n-side electrode) is solidly provided on the back surface of the substrate 100. As an example, the first electrode 110 has a three-layer structure of AuGe/Ni/Au. In the three-layer structure, as an example, the thickness of the AuGe layer is 150 nm, the thickness of the Ni layer is 50 nm, and the thickness of the Au layer is 200 nm.

### (First Multilayer Film Reflector)

The first multilayer film reflector 101 is, for example, a semiconductor multilayer film reflector. The multilayer film reflector is also referred to as a distributed Bragg reflector. A semiconductor multilayer film reflector which is a type of multilayer film reflector (distributed Bragg reflector) has low light absorption, high reflectance, and conductivity. The first multilayer film reflector 101 is also referred to as a lower DBR.

As an example, the first multilayer film reflector 101 is a semiconductor multilayer film reflector of a first conductivity type (for example, n-type), and has a structure in which a plurality of types (for example, two types) of semiconductor layers (refractive index layers) having different refractive indexes is alternately laminated with an optical thickness of ¼ (λ/4) of the oscillation wavelength λ. Each refractive index layer of the first multilayer film reflector 101 is constituted by a first conductivity type (for example, n-type) AlGaAs-based compound semiconductor. Specifically, in the first multilayer film reflector 101, a high refractive index layer constituted by GaAs and a low refractive index layer constituted by AlGaAs are alternately laminated. Here, the number of pairs of the high refractive index layer and the low refractive index layer is 18.

### (First Cladding Layer)

The first cladding layer 102 is constituted by a first conductivity type (for example, n-type) AlGaAs-based compound semiconductor. The central region of the first cladding layer 102 is surrounded by an ion implantation region IIA (dark gray region in FIG. 1B) as a carrier confinement portion. The ion implantation region IIA is a region into which ions such as boron (B) ions and hydrogen (H) ions are implanted, for example.

### (Active Layer)

The active layer 103 has a quantum well structure including a quantum well layer constituted by, for example, an InGaAs-based compound semiconductor and a barrier layer. This quantum well structure may be a single quantum well structure (QW structure) or a multiple quantum well structure (MQW structure). As an example, the quantum well structure of the active layer 103 is designed so that the oscillation wavelength A is 920 nm to 960 nm.

As an example, the light emitting region LA is a central region of the active layer 103 and is surrounded by an ion implantation region IIA (dark gray region in FIG. 1B) which is a carrier confinement portion. The ion implantation region IIA has higher resistance than the light emitting region LA.

As an example, the light emitting region LA has a substantially circular shape in plan view, and has a diameter of, for example, about 5 μm.

### (Second Cladding Layer)

The second cladding layer 104 is constituted by a second conductivity type (for example, p-type) AlGaAs-based compound semiconductor. The central region of the second cladding layer 104 is surrounded by the ion implantation region IIA (dark gray region in FIG. 1B) as a carrier confinement portion.

The resonator length (total thickness of first cladding layer 102, active layer 103, and second cladding layer 104) of the resonator R is preferably an integral multiple of ½ of the oscillation wavelength λ, for example, λ/2.

The thickness of the ion implantation region IIA is only required to be designed so as to suppress the spread of carriers in the active layer 103, and is, for example, about the same as the thickness (resonator length) of the resonator R (for example, 200 nm).

### (Second Multilayer Film Reflector)

As an example, the second multilayer film reflector 105 is a semiconductor multilayer film reflector of the second conductivity type, and has a structure in which a plurality of types (for example, two types) of semiconductor layers (refractive index layers) having different refractive indexes is alternately laminated with an optical thickness of ¼ wavelength of the oscillation wavelength. Each refractive index layer of the second multilayer film reflector 105 is constituted by an AlGaAs-based compound semiconductor of the second conductivity type (for example, p-type). Specifically, in the second multilayer film reflector 105, a high refractive index layer constituted by GaAs and a low refractive index layer constituted by AlGaAs are alternately laminated. Here, the film thickness of each refractive index layer is set to be the same as the film thickness of the corresponding refractive index layer of the first multilayer film reflector 101, and the number of pairs of the high refractive index layer and the low refractive index layer is 37 pairs. That is, the reflectance of the second multilayer film reflector 105 is set higher than the reflectance of the first multilayer film reflector 101.

### (MOSFET)

As an example, the MOSFET is provided on the surface of the second multilayer film reflector 105 on the side opposite to the active layer 103 side in the second structure ST2.

Here, as an example, the second structure ST2 further includes a semiconductor layer 106 including an n-type semiconductor region 106n that is a semiconductor region of the first conductivity type (for example, n-type) disposed on the surface of the second multilayer film reflector 105 on the side opposite to the active layer 103 side. The n-type semiconductor region 106n is constituted by, for example, an n-type AlGaAs-based compound semiconductor. The thickness of the semiconductor layer 106 is, for example, 10 nm to several μm, and is 500 nm here.

The MOSFET includes a drain region 106D (first impurity region) provided at a position corresponding to the light emitting region LA in the semiconductor layer 106, and a source region 106S (second impurity region) provided around the drain region 106D in the semiconductor layer 106. The drain region 106D and the source region 106S are both impurity regions provided in the semiconductor layer 106. Examples of impurities in the impurity region include Zn.

The drain region 106D is, for example, a region having a substantially circular shape in plan view. The drain region 106D is in contact with the second multilayer film reflector 105. The drain region 106D is provided in substantially the entire region in the thickness direction of the semiconductor layer 106. That is, the thickness of the drain region 106D is, for example, equivalent to the thickness of the semiconductor layer 106 (for example, 500 nm).

As an example, the source region 106S surrounds the drain region 106D. That is, the source region 106S is a frame-shaped (for example, annular) region.

An n-type semiconductor region 106n (several nm to several hundred nm, preferably several tens nm) is interposed between the source region 106S and the drain region 106D, and the source region 106S and the drain region 106D are not energized.

The source region 106S is not in contact with the second multilayer film reflector 105. More specifically, the source region 106S is provided on the semiconductor layer 106. The thickness of the source region 106S is, for example, 200 nm.

An n-type semiconductor region 106n (for example, 300 nm) is interposed between the source region 106S and the second multilayer film reflector 105, and the source region 106S and the second multilayer film reflector 105 are not energized.

The electrical resistance between the source region 106S and the first multilayer film reflector 101 is set to be larger than the electrical resistance between the drain region 106D and the first multilayer film reflector 101.

The MOSFET further includes a gate electrode 109 provided at a position of the second structure ST2 corresponding to the drain region 106D and the source region 106S, a gate electrode 109, and a gate insulating film 108 provided between the drain region 106D and the source region 106S.

The gate electrode 109 is provided with an opening serving as the emission port Ex at a position corresponding to the light emitting region LA. As an example, the gate electrode 109 is a frame-shaped (for example, annular) electrode having a circular emission port Ex on the inner diameter side. As an example, the gate electrode 109 has a three-layer structure of Ti/Pt/Au. In the three-layer structure, as an example, the thickness of the Ti layer is 50 nm, the thickness of the Pt layer is 100 nm, and the thickness of the Au layer is 200 nm.

The gate insulating film 108 is constituted by a dielectric such as SiO₂, SiN, or SiON.

The MOSFET further includes a second electrode 107 as a source electrode provided at a position of the second structure ST2 in contact with the source region 106S, and a first electrode 110 as a drain electrode provided at a position of the first structure ST1 opposite to the active layer 103 side of the first multilayer film reflector 101.

The second electrode 107 is a frame-shaped electrode disposed so as to surround the gate electrode 109. The second electrode 107 has both a function as an anode electrode for allowing a current to flow into the surface emitting laser element 10 and a function as a source electrode of a MOSFET. As an example, the second electrode 107 has a three-layer structure of Ti/Pt/Au. In the three-layer structure, as an example, the thickness of the Ti layer is 50 nm, the thickness of the Pt layer is 100 nm, and the thickness of the Au layer is 200 nm.

The first electrode 110 has both a function as a cathode electrode that causes a current flowing through the surface emitting laser element 10 to flow out and a function as a drain electrode of a MOSFET.

### (2) Operation of Surface Emitting Laser Element

Hereinafter, the operation of the surface emitting laser element 10 will be described.

For driving the surface emitting laser element 10, the first power supply V1 for generating the current injected into the light emitting region LA and the second power supply V2 for driving the MOSFET are used.

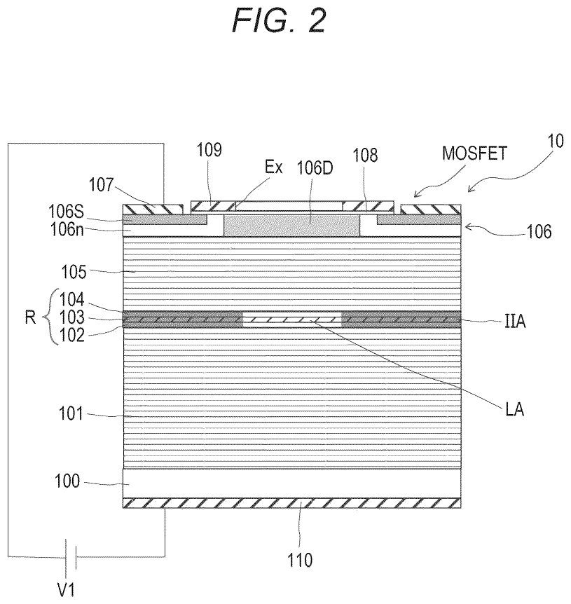

In the surface emitting laser element 10, as an example, as illustrated in FIG. 2, the first electrode 110 is connected to the cathode of the first power supply V1 in advance, and the second electrode 107 is connected to the anode of the first power supply V1. That is, in the surface emitting laser element 10, the voltage (driving voltage) of the first power supply V1 is applied between the first and second electrodes 110 and 107 during standby.

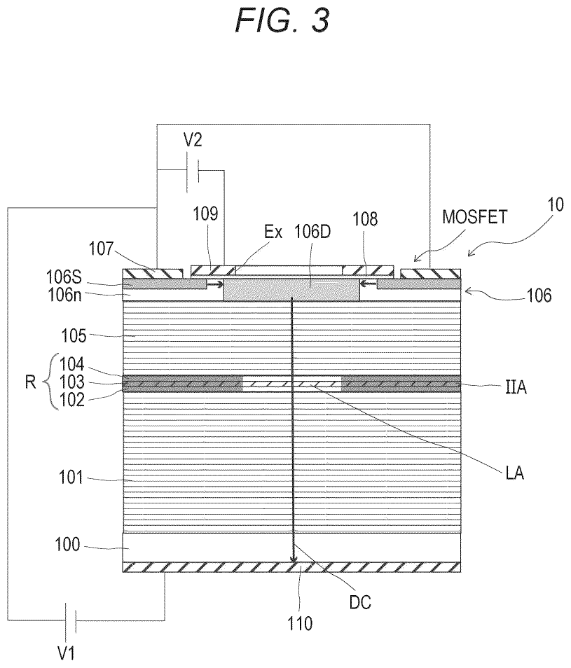

In the surface emitting laser element 10, as an example, as illustrated in FIG. 3, at the time of driving, an anode of the second power supply V2 is further connected to the second electrode 107, a cathode of the second power supply V2 is connected to the gate electrode 109, and a voltage (gate voltage) of the second power supply V2 is applied between the gate electrode 109 and the second electrode 107. At this time, a channel is formed between the source region 106S and the drain region 106D, and a current flows from the source region 106S to the drain region 106D. The current (drain current DC) flowing to the drain region 106D passes through the second multilayer film reflector 105 and the second cladding layer 104, and is injected into the light emitting region LA of the active layer 103 while being narrowed by the ion implantation region IIA. At this time, the light emitting region LA emits light, and the light reciprocates between the first and second multilayer film reflectors 101 and 105 while being amplified by the active layer 103. When the oscillation condition is satisfied, the light is emitted as laser light from the emission port Ex via the drain region 106D. The current (drain current DC) injected into the light emitting region LA reaches the first electrode 110 via the first cladding layer 102, the first multilayer film reflector 101, and the substrate 100, and flows out from the first electrode 110 to the cathode of the first power supply V1.

In the surface emitting laser element 10, when the application of the gate voltage is released (when the driving of the MOSFET is stopped), a channel is not formed between the source region 106S and the drain region 106D, and a current does not flow from the source region 106S to the drain region 106D.

As described above, the surface emitting laser element 10 can control the injection of the current to the light emitting region LA by applying/releasing the gate voltage of the MOSFET (can switch on/off of the energization to the light emitting region LA).

### (3) Method for Manufacturing Surface Emitting Laser Element

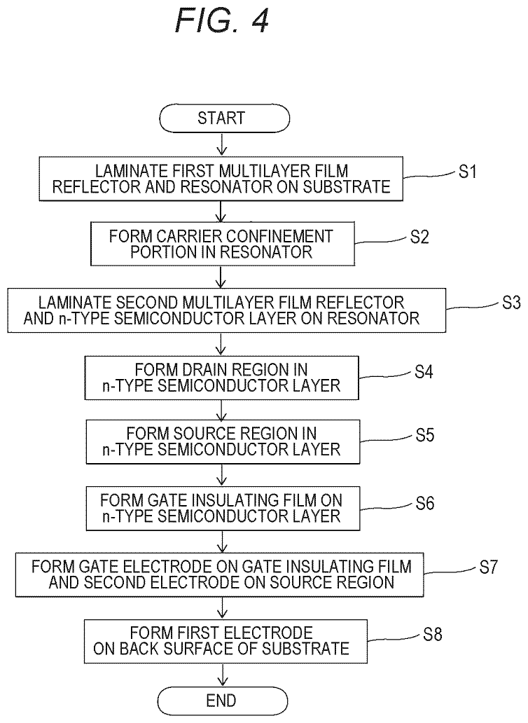

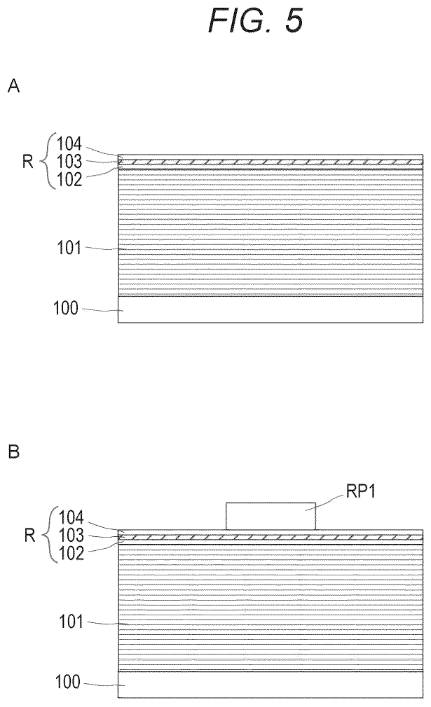

Hereinafter, a method for manufacturing the surface emitting laser element 10 will be described with reference to the flowchart of FIG. 4 and the cross-sectional views of FIGS. 5A to 13B.

Here, as an example, a plurality of surface emitting laser elements 10 is simultaneously generated on one wafer which is a base material of the substrate 100 by a semiconductor manufacturing method using a semiconductor manufacturing apparatus. Next, a plurality of continuous and integrated surface emitting laser elements 10 is separated from each other by dicing to obtain a plurality of chip-shaped surface emitting laser elements 10.

Alternatively, a plurality of surface emitting laser arrays in which a plurality of surface emitting laser elements 10 is arranged in an array on one wafer which is a base material of the substrate 100 is simultaneously generated, and a plurality of continuous and integrated surface emitting laser arrays is separated from each other by dicing to obtain a plurality of chip-shaped surface emitting laser arrays.

In the first step S1, the first multilayer film reflector 101 and the resonator R are laminated on the substrate 100. Specifically, as illustrated in FIG. 5A, the first multilayer film reflector 101, the first cladding layer 102, the active layer 103, and the second cladding layer 104 are laminated in this order on the substrate 100 by using a chemical vapor deposition (CVD) method, for example, a metal organic chemical vapor deposition (MOCVD) method.

In the next step S2, the ion implantation region IIA as the carrier confinement portion is formed on the resonator R.

Specifically, first, a resist pattern RP1 is formed on a region corresponding to the light emitting region LA of the resonator R (see FIG. 5B).

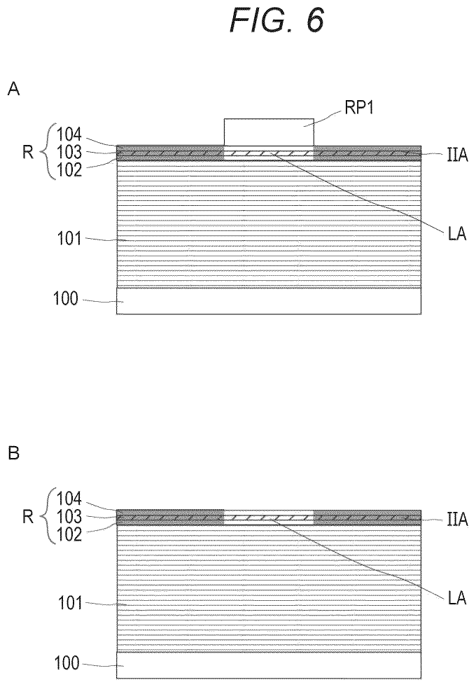

Next, for example, B ions are implanted into the resonator R using the resist pattern RP1 as a mask to form an ion implantation region IIA surrounding a region corresponding to the light emitting region LA of the resonator R (see FIG. 6A).

Finally, the resist pattern RP1 is removed (see FIG. 6B).

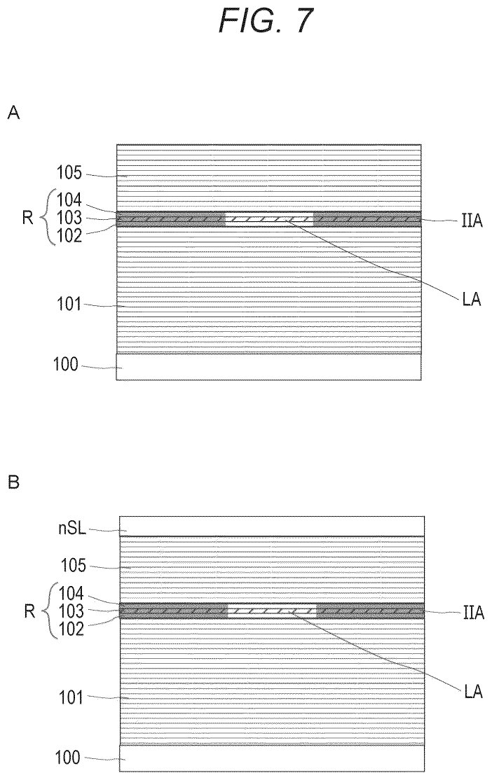

In the next step S3, the n-type semiconductor layer nSL having a conductivity type (for example, n-type) different from those of the second multilayer film reflector 105 and the second multilayer film reflector 105 is laminated on the resonator R (see FIGS. 7A and 7B). Specifically, the second multilayer film reflector 105 and the n-type semiconductor layer nSL are laminated in this order on the resonator R in which the ion implantation region IIA is formed by the regrowth. The n-type semiconductor layer nSL is constituted by, for example, an n-type semiconductor such as an AlGaAs-based compound semiconductor.

In the next step S4, the drain region 106D is formed in the n-type semiconductor layer nSL.

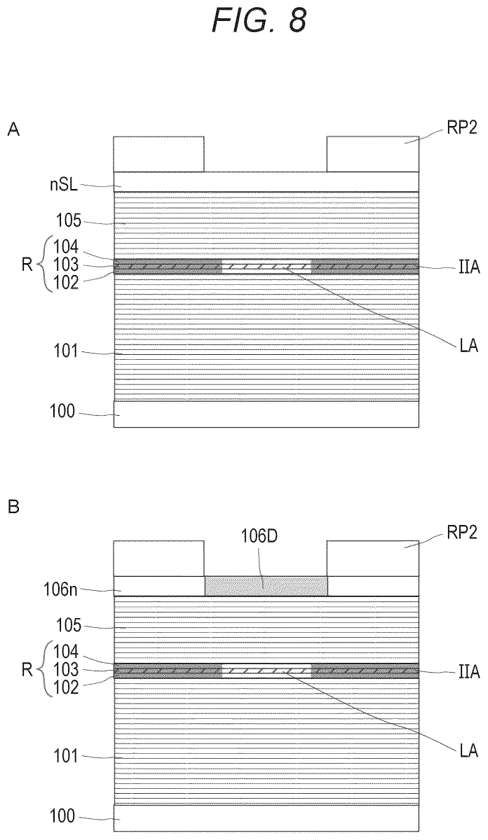

Specifically, first, a resist pattern RP2 is formed on a region other than the region where the drain region 106D of the n-type semiconductor layer nSL is to be formed (see FIG. 8A).

Next, using the resist pattern RP2 as a mask, Zn is vapor-phase diffused while being heated at, for example, 550° C. to form the drain region 106D in the n-type semiconductor layer nSL (see FIG. 8B). At this time, Zn is diffused throughout the n-type semiconductor layer nSL in the thickness direction. As a result, the drain region 106D surrounded by the n-type semiconductor region 106n is formed.

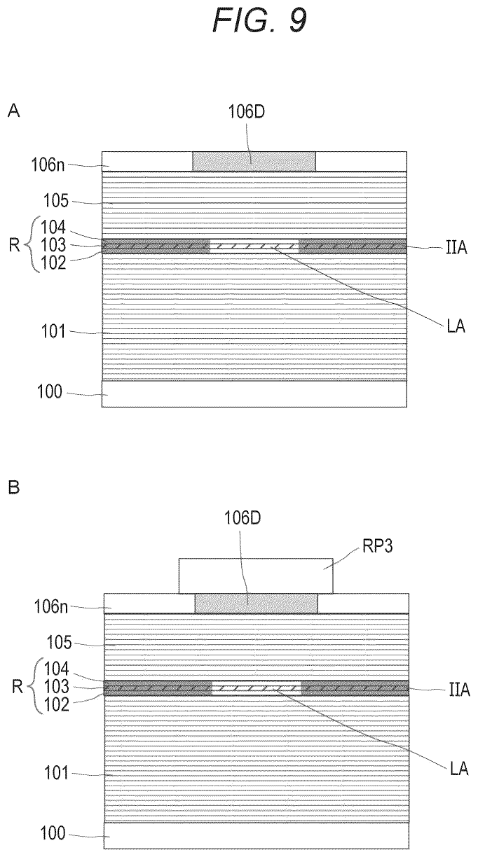

Finally, the resist pattern RP2 is removed (see FIG. 9A).

In the next step S5, a source region is formed in the n-type semiconductor layer nSL.

Specifically, first, a resist pattern RP3 is formed on a region other than a region where the source region 106S of the n-type semiconductor layer nSL is to be formed (see FIG. 9B).

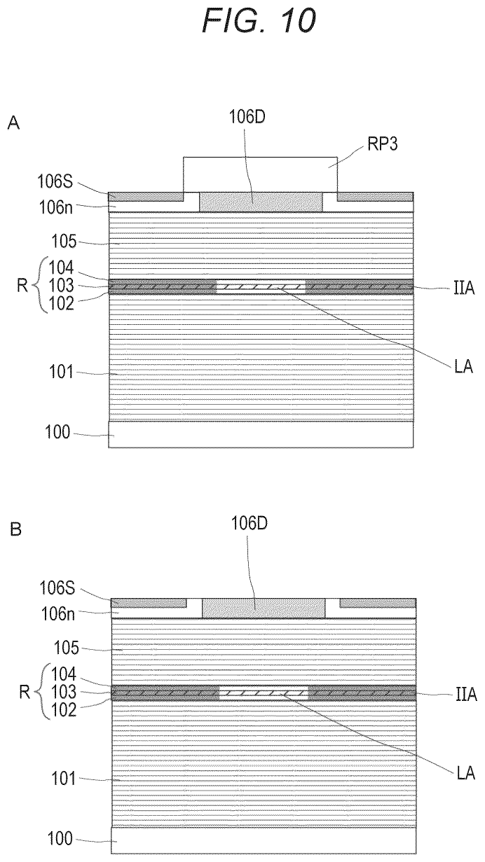

Next, using the resist pattern RP3 as a mask, Zn is vapor-phase diffused while being heated at, for example, 550° C. to form the source region 106S in the n-type semiconductor layer nSL (see FIG. 10A). At this time, Zn is diffused only in the upper portion of the n-type semiconductor layer nSL in the thickness direction. As a result, the source region 106S surrounding the drain region 106D is formed, the source region 106S being separated from both the drain region 106D and the second multilayer film reflector 105 by the n-type semiconductor region 106n.

Finally, the resist pattern RP3 is removed (see FIG. 10B).

In the next step S6, the gate insulating film 108 is formed on the n-type semiconductor layer nSL.

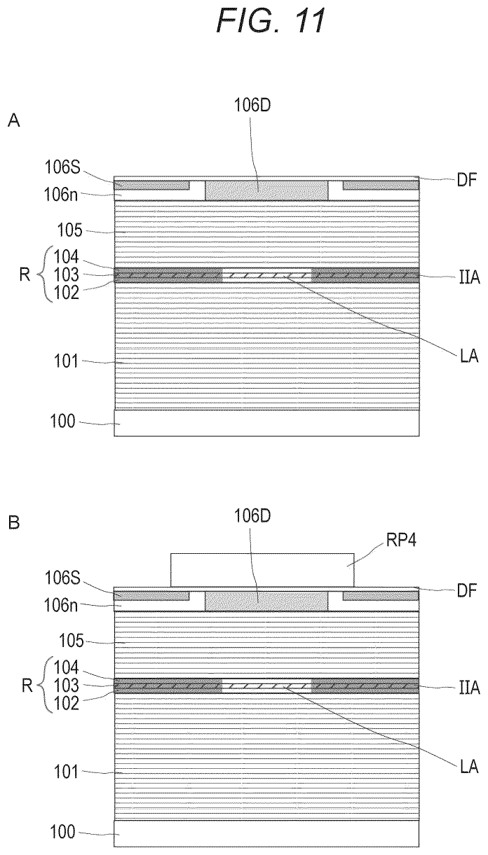

Specifically, first, the dielectric film DF to be the gate insulating film 108 is formed on the n-type semiconductor layer nSL in which the drain region 106D and the source region 106S are formed (FIG. 11A).

Next, a resist pattern RP4 is formed on regions of the dielectric film DF corresponding to the inner peripheral portions of the drain region 106D and the source region 106S (see FIG. 11B).

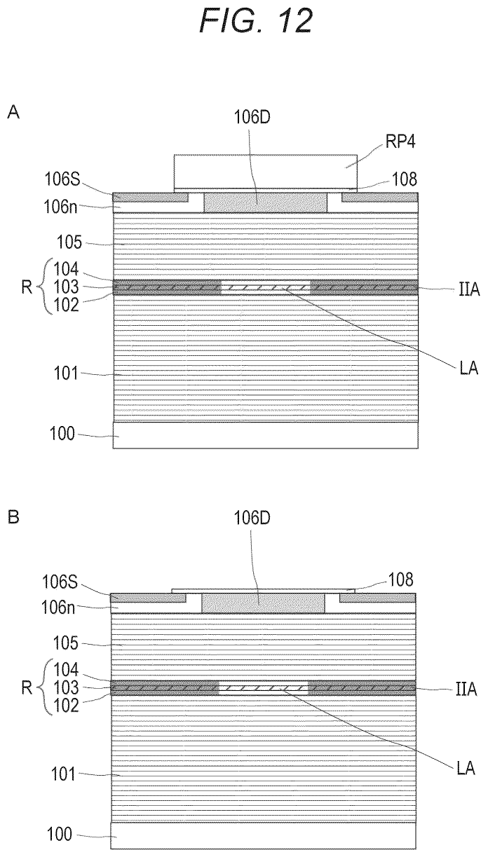

Next, the dielectric film DF is etched using the resist pattern RP4 as a mask to form the gate insulating film 108 (see FIG. 12A).

Finally, the resist pattern RP4 is removed by etching (see FIG. 12B).

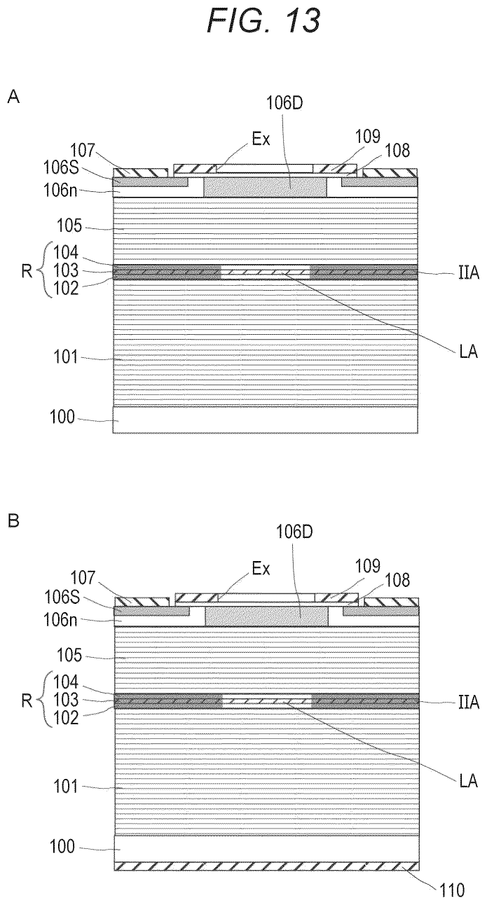

In the next step S7, the gate electrode 109 is formed on the gate insulating film 108, and the second electrode 107 is formed on the source region 106S (see FIG. 13A).

Specifically, the gate electrode 109 and the second electrode 107 are formed by a lift-off method using a photoresist.

More specifically, first, a resist is applied to a portion other than a portion where the gate electrode 109 and the second electrode 107 are to be formed, and an electrode material (for example, Ti/Pt/Au) is formed on the entire surface by vacuum deposition or sputtering. Next, electrode materials other than the electrode materials to be the gate electrode 109 and the second electrode 107 are removed together with the resist. As a result, only the electrode materials of the gate electrode 109 and the second electrode 107 remain.

In the final step S8, the first electrode 110 is formed on the back surface of the substrate 100 (see FIG. 13B).

Specifically, an electrode material (for example, AuGe/Ni/Au) is solidly formed on the back surface of the substrate 100 by vacuum deposition or sputtering.

Thereafter, processing such as annealing is performed to form a plurality of surface emitting laser elements 10 on one wafer. Thereafter, the plurality of surface emitting laser elements 10 is separated for each element by dicing to obtain a plurality of chip-shaped surface emitting laser elements 10.

Alternatively, processing such as annealing is performed to form a plurality of surface emitting laser arrays including the plurality of surface emitting laser elements 10 on one wafer. Thereafter, the plurality of surface emitting laser arrays is separated for each array by dicing to obtain a plurality of chip-shaped surface emitting laser arrays.

### (4) Effects of Surface Emitting Laser Element and Method for Manufacturing Surface Emitting Laser Element

Hereinafter, effects of the surface emitting laser element 10 and the method for manufacturing the surface emitting laser element 10 will be described.

A surface emitting laser element 10 according to the first embodiment includes a first structure ST1 including a first multilayer film reflector 101, a second structure ST2 including a second multilayer film reflector 105, and a resonator R arranged between the first and second structures ST1 and ST2. The resonator R includes an active layer 103 in which at least a light emitting region LA is arranged between the first and second multilayer film reflectors 101 and 105. The second structure ST2 is provided with a MOSFET as an example of a field effect transistor that controls injection of a current into the light emitting region LA.

In this case, since the injection (energization) of the current into the light emitting region LA can be controlled by applying the voltage to the MOSFET, it is possible to suppress an increase in the driving voltage not only in a case where the light emitting region (light emitting area) is large and the series resistance is low but also in a case where the light emitting region is small and the series resistance is high.

As a result, according to the surface emitting laser element 10 of the first embodiment, it is possible to provide the surface emitting laser element capable of suppressing an increase in the driving voltage regardless of the size of the light emitting region.

Furthermore, for example, even in a surface emitting laser array in which a plurality of surface emitting laser elements 10 is arranged at high density, it is possible to selectively drive at least one surface emitting laser element 10 while suppressing an increase in driving voltage.

Therefore, for example, since the driving load of the laser driver that drives each surface emitting laser element 10 is reduced, it is possible to perform control with an inexpensive and high-performance Si-based laser driver even if the light emitting region is small.

On the other hand, in a case where the surface emitting laser array element is driven using a laser driver having a bipolar transistor, a current is injected from the bipolar transistor to the light emitting region. Therefore, particularly in a case where the light emitting region is small and the series resistance is high, the driving voltage of the laser driver becomes high, and there is a possibility that the driving voltage becomes insufficient. That is, in this case, it is not possible to suppress an increase in the driving voltage of the laser driver regardless of the size of the light emitting region. In addition, in the laser driver, since it is necessary to inject a current into the light emitting region by the bipolar transistor, high power is required.

The MOSFET preferably has a drain region 106D provided at a position of the second structure ST2 corresponding to the light emitting region LA and a source region 106S of the second structure ST2 provided around the drain region 106D. As a result, a current can be efficiently injected from the source region 106S to the light emitting region LA via the drain region 106D.

The electrical resistance between the source region 106S and the first multilayer film reflector 101 is larger than the electrical resistance between the drain region 106D and the first multilayer film reflector 101. This makes it possible to reliably flow a current from the source region 106S to the drain region 106D at the time of current injection into the light emitting region LA.

The source region 106S preferably surrounds the drain region 106D. As a result, a current can efficiently flow from the periphery of the drain region 106D to the drain region 106D.

The MOSFET preferably further includes a gate electrode 109 provided at a position of the second structure ST2 corresponding to the drain region 106D and the source region 106S, a gate electrode 109, and a gate insulating film 108 provided between the drain region 106D and the source region 106S. Thus, the gate electrode 109 can be insulated from the source region 106S and the drain region 106D.

The MOSFET preferably further includes a second electrode 107 (source electrode) provided at a position of the second structure ST2 in contact with the source region 106S, and a first electrode 110 (drain electrode) provided at a position of the first structure ST1 opposite to the active layer 103 side of the first multilayer film reflector 101.

As an example, the drain region 106D and the source region 106S are provided at positions on the side of the second structure ST2 opposite to the active layer 103 side of the second multilayer film reflector 105.

More specifically, the second structure ST2 may further include the semiconductor layer 106 including the n-type semiconductor region 106n disposed on the surface of the second multilayer film reflector 105 on the side opposite to the active layer 103 side, and the drain region 106D and the source region 106S may be impurity regions provided in the semiconductor layer 106. Thus, the drain region 106D and the source region 106S can be easily formed.

The drain region 106D is in contact with the second multilayer film reflector 105, and the source region 106S is not in contact with the second multilayer film reflector 105. As a result, it is possible to prevent the drain region 106D and the source region 106S from being electrically connected via the second multilayer film reflector 105, to reliably flow a current from the source region 106S to the drain region 106D, and to inject the current flowing into the drain region 106D into the light emitting region LA via the second multilayer film reflector 105.

The resonator R is provided with an ion implantation region IIA as a carrier confinement portion surrounding the light emitting region LA. As a result, the current injected into the light emitting region LA can be narrowed, and the current injection efficiency into the light emitting region LA can be enhanced.

The ion implantation region IIA as the carrier confinement portion has higher resistance than the light emitting region LA. As a result, the current injected into the light emitting region LA can be reliably narrowed, and the current injection efficiency into the light emitting region LA can be reliably enhanced.

The light source device 1 includes a surface emitting laser element 10, a first power supply V1 for generating a current injected into the light emitting region LA of the surface emitting laser element 10, and a second power supply V2 for driving a field effect transistor (for example, MOSFET) of the surface emitting laser element 10. As a result, since the surface emitting laser element 10 can be controlled by the inexpensive and high-performance Si-based laser driver, a high-definition and inexpensive light source module can be realized.

The method for manufacturing the surface emitting laser element 10 according to the first embodiment includes a step of laminating the first multilayer film reflector 101 and the resonator R including the active layer 103 in this order on the substrate 100, and a step of forming the second structure ST2 which is a structure including the second multilayer film reflector 105 on the resonator R. In the step of forming the second structure ST2, a MOSFET is formed as an example of a field effect transistor having a drain region 106D at a position of the active layer 103 corresponding to a light emitting region LA (predetermined region) which is a region surrounded by an ion implantation region IIA as a carrier confinement portion, and having a source region 106S at a position corresponding to a periphery of the light emitting region LA.

According to the method for manufacturing the surface emitting laser element 10, the surface emitting laser element 10 can be efficiently manufactured.

### <3. Surface Emitting Laser Element According to Second Embodiment of Present Technology>

### (1) Configuration of Surface Emitting Laser Element

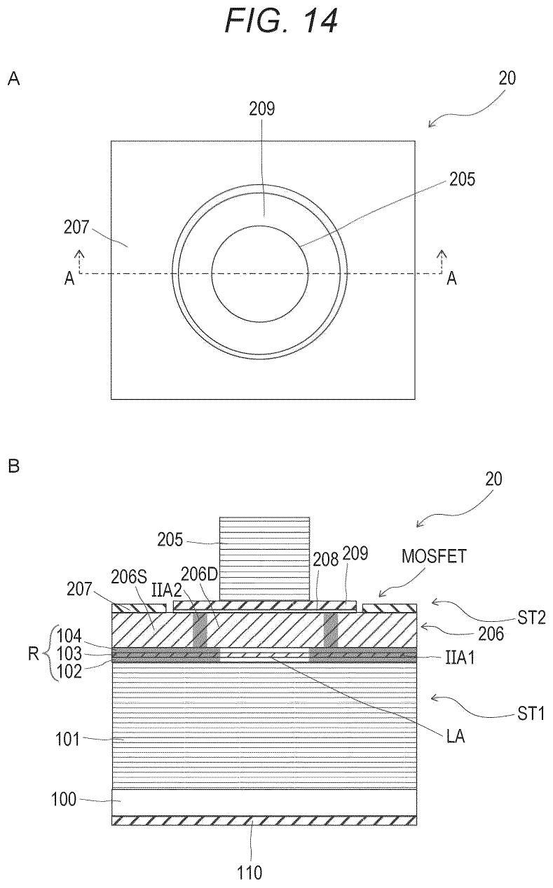

Hereinafter, a configuration of a surface emitting laser element according to a second embodiment of the present technology will be described with reference to FIGS. 14A and 14B. FIG. 14A is a plan view of a surface emitting laser element according to the second embodiment of the present technology. FIG. 14B is a cross-sectional view of the surface emitting laser element according to the second embodiment of the present technology. More specifically, FIG. 14B is a cross-sectional view taken along line A-A of FIG. 14A.

In the surface emitting laser element 20 according to the second embodiment, as illustrated in FIG. 14B, the second structure ST2 includes a semiconductor layer 206 disposed between the second multilayer film reflector 205 and the resonator R. The semiconductor layer 206 is constituted by, for example, a p-type AlGaAs-based compound semiconductor.

In the surface emitting laser element 20, the drain region 206D of the MOSFET is a region corresponding to the light emitting region LA of the semiconductor layer 206, and the source region 206S is a region around the drain region 206D of the semiconductor layer 206. More specifically, the source region 206S is a region surrounding the drain region 206D of the semiconductor layer 206.

The resonator R is provided with a first ion implantation region IIA1 as a carrier confinement portion surrounding the light emitting region LA. The first ion implantation region IIA1 is substantially the same as the ion implantation region IIA described above.

The second ion implantation region IIA2 is provided between the drain region 106D and the source region 106S in the semiconductor layer 206. More specifically, as an example, the second ion implantation region IIA2 is provided in a frame shape (for example, an annular shape) so as to surround the drain region 106D. The second ion implantation region IIA2 is provided in the entire region in the thickness direction of the semiconductor layer 206.

That is, the drain region 206D and the source region 206S are electrically separated (insulated) by the second ion implantation region IIA2.

The interval between the drain region 206D and the source region 206S, that is, the radial thickness of the second ion implantation region IIA2 is, for example, several nm to several hundred nm (preferably several 10 nm).

The second structure ST2 further includes a transparent conductive film 209 as a gate electrode in which a part corresponding to the light emitting region LA is disposed between the second multilayer film reflector 205 and the semiconductor layer 206 and the other part is exposed. As an example, the cathode of the second power supply V2 is connected to the exposed part of the transparent conductive film 209. Examples of the material of the transparent conductive film 209 include In₂O₃ (for example, ITO), ZnO (for example, AZO), and SnO₂.

A gate insulating film 208 is disposed between the transparent conductive film 209 and the semiconductor layer 206. The gate insulating film 208 is constituted by a dielectric such as SiO₂, SiN, or SiON.

A dielectric multilayer film reflector as the second multilayer film reflector 205 is disposed on a region of the transparent conductive film 209 corresponding to the light emitting region LA. The reflectance of the second multilayer film reflector 205 is set to be lower than the reflectance of the first multilayer film reflector 101.

### (2) Operation of Surface Emitting Laser Element

Hereinafter, the operation of the surface emitting laser element 20 will be described.

For driving the surface emitting laser element 20, the first power supply V1 for generating the current injected into the light emitting region LA and the second power supply V2 for driving the MOSFET are used.

In the surface emitting laser element 20, as an example, the first electrode 110 is connected to the cathode of the first power supply V1 in advance, and a second electrode 207 is connected to the anode of the first power supply V1. That is, in the surface emitting laser element 20, the voltage (driving voltage) of the first power supply V1 is applied between the first and second electrodes 110 and 207 during standby.

In the surface emitting laser element 20, as an example, at the time of driving, an anode of the second power supply V2 is further connected to the second electrode 207, a cathode of the second power supply V2 is connected to the transparent conductive film 209 as a gate electrode, and a voltage (gate voltage) of the second power supply V2 is applied between the transparent conductive film 209 and the second electrode 207. At this time, a channel is formed between the source region 206S and the drain region 206D, and a current flows from the source region 206S to the drain region 206D. The current flowing to the drain region 206D passes through the second cladding layer 104 and is injected into the light emitting region LA of the active layer 103 while being narrowed in the first ion implantation region IIA1. At this time, the light emitting region LA emits light, and the light reciprocates between the first and second multilayer film reflectors 101 and 205 while being amplified by the active layer 103, and is emitted as laser light from the upper surface of the second multilayer film reflector 205 when an oscillation condition is satisfied. The current injected into the light emitting region LA reaches the first electrode 110 via the first cladding layer 102, the first multilayer film reflector 101, and the substrate 100, and flows out from the first electrode 110 to the cathode of the first power supply V1.

In the surface emitting laser element 20, when the application of the gate voltage is released, a channel is not formed between the source region 206S and the drain region 206D, and a current does not flow from the source region 206S to the drain region 206D.

As described above, the surface emitting laser element 20 can control the injection of the current to the light emitting region LA by applying/releasing the gate voltage of the MOSFET (can switch on/off of the energization to the light emitting region LA).

### (3) Method for Manufacturing Surface Emitting Laser Element

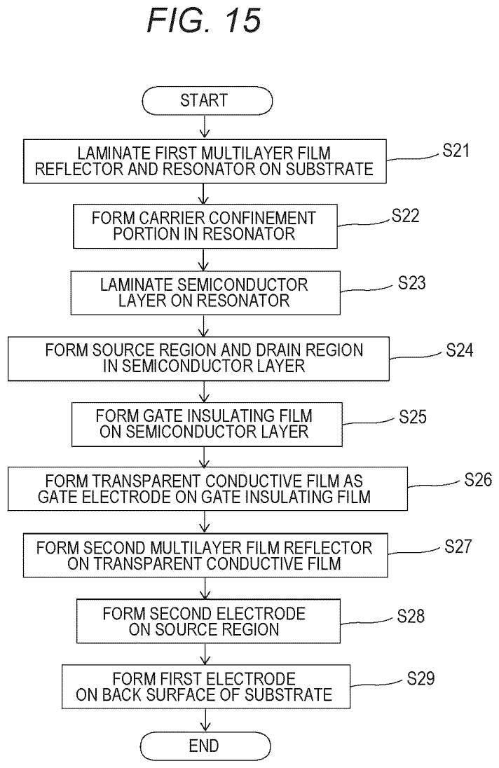

Hereinafter, a method for manufacturing the surface emitting laser element 20 will be described with reference to the flowchart of FIG. 15, and cross-sectional views of FIGS. 5A to 6B and FIGS. 16A to 23.

Here, as an example, a plurality of surface emitting laser elements 20 is simultaneously generated on one wafer which is a base material of the substrate 100 by a semiconductor manufacturing method using a semiconductor manufacturing apparatus. Next, the plurality of continuous and integrated surface emitting laser elements 20 is separated from each other by dicing to obtain a plurality of chip-shaped surface emitting laser elements 20.

Alternatively, as an example, a plurality of surface emitting laser arrays in which a plurality of surface emitting laser elements 20 is arranged in an array on one wafer which is a base material of the substrate 100 is simultaneously generated, and a plurality of continuous and integrated surface emitting laser arrays is separated from each other by dicing to obtain a plurality of chip-shaped surface emitting laser arrays.

In the first step S21, the first multilayer film reflector 101 and the resonator R are laminated on the substrate 100. Specifically, the first multilayer film reflector 101, the first cladding layer 102, the active layer 103, and the second cladding layer 104 are laminated in this order on the substrate 100 using a chemical vapor deposition (CVD) method, for example, a metal organic chemical vapor deposition (MOCVD) method (see FIG. 5A).

In the next step S22, the ion implantation region IIA as the carrier confinement portion is formed on the resonator R.

Specifically, first, a resist pattern RP1 is formed on a region corresponding to the light emitting region LA of the resonator R (see FIG. 5B).

Next, for example, B ions are implanted into the resonator R using the resist pattern RP1 as a mask to form an ion implantation region IIA surrounding a region corresponding to the light emitting region LA of the resonator R (see FIG. 6A).

Finally, the resist pattern RP1 is removed (see FIG. 6B).

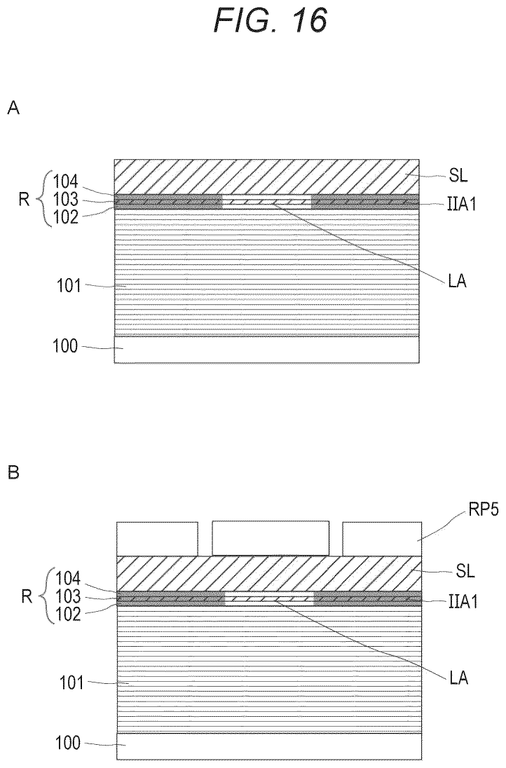

In the next step S23, the semiconductor layer SL is laminated on the resonator R (see FIG. 16A). Specifically, the semiconductor layer SL to be a base material of the semiconductor layer 206 is laminated on the resonator R in which the ion implantation region IIA is formed by regrowth.

In the next step S24, the source region 206S and the drain region 206D are formed in the semiconductor layer SL.

Specifically, first, a resist pattern RP5 is formed on a region other than the regions to be the source region 206S and the drain region 206D of the semiconductor layer SL (see FIG. 16B).

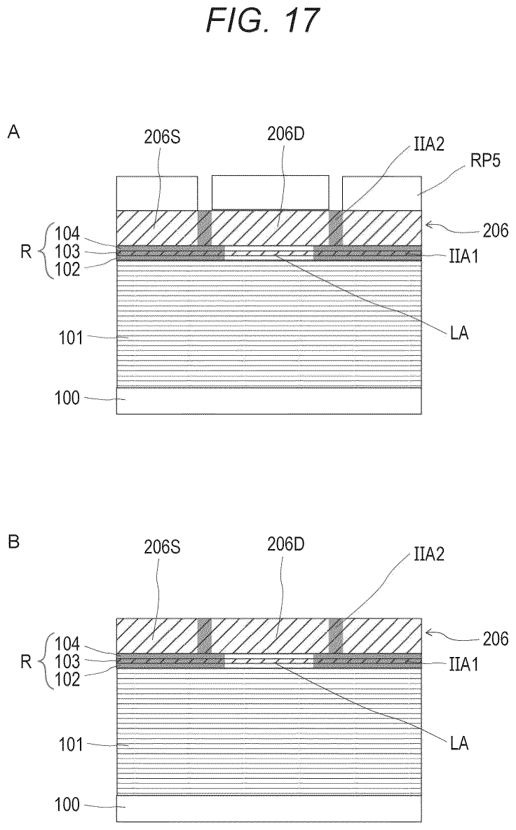

Next, using the resist pattern RP5 as a mask, for example, B ions are implanted from the upper surface of the semiconductor layer SL to form a second ion implantation region IIA2 (see FIG. 17A). At this time, the depth of the ion implantation reaches the interface between the semiconductor layer SL and the resonator R, and the second ion implantation region IIA2 is formed in the entire region in the thickness direction of the semiconductor layer SL. As a result, the source region 206S and the drain region 206D insulated from each other are formed in the semiconductor layer SL.

Finally, the resist pattern RP5 is removed (see FIG. 17B). As a result, the semiconductor layer 206 is exposed.

In the next step S25, the gate insulating film 208 is formed on the semiconductor layer 206.

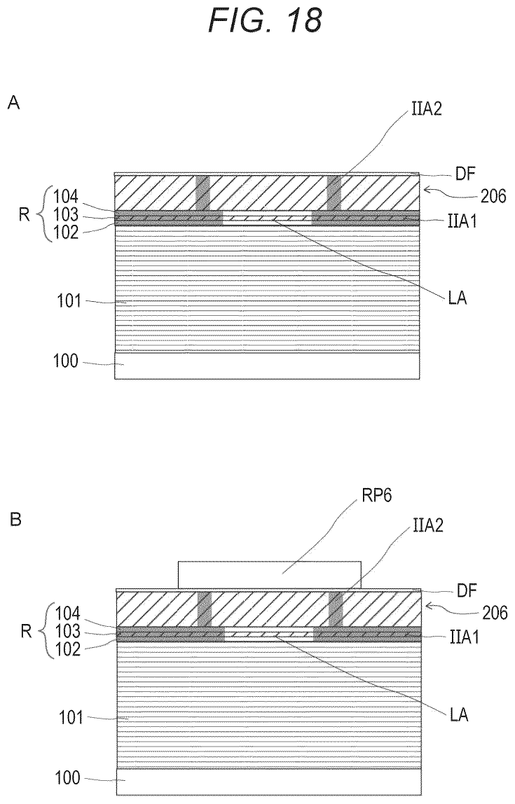

Specifically, first, a dielectric film DF to be the gate insulating film 208 is formed on the semiconductor layer 206 (FIG. 18A).

Next, a resist pattern RP6 is formed on a region of the dielectric film DF corresponding to the inner peripheral portion of the source region 206S and the drain region 206D (see FIG. 18B).

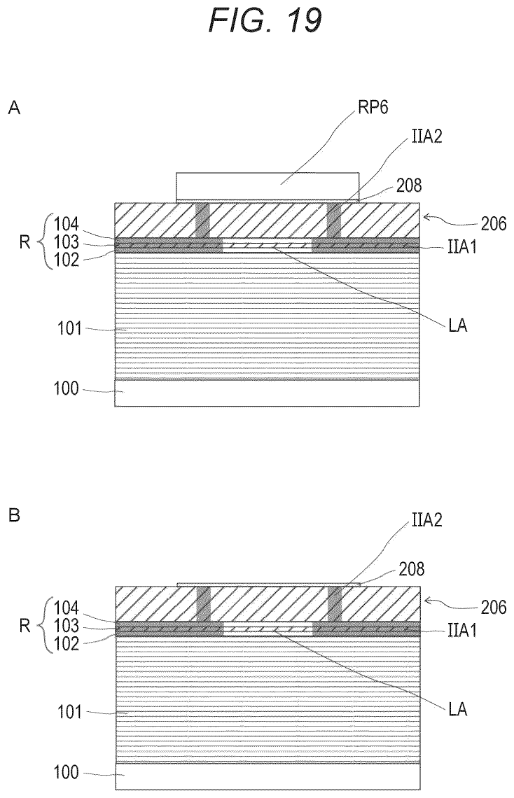

Next, the dielectric film DF is etched using the resist pattern RP6 as a mask to form the gate insulating film 208 (see FIG. 19A).

Finally, the resist pattern RP6 is removed (see FIG. 19B).

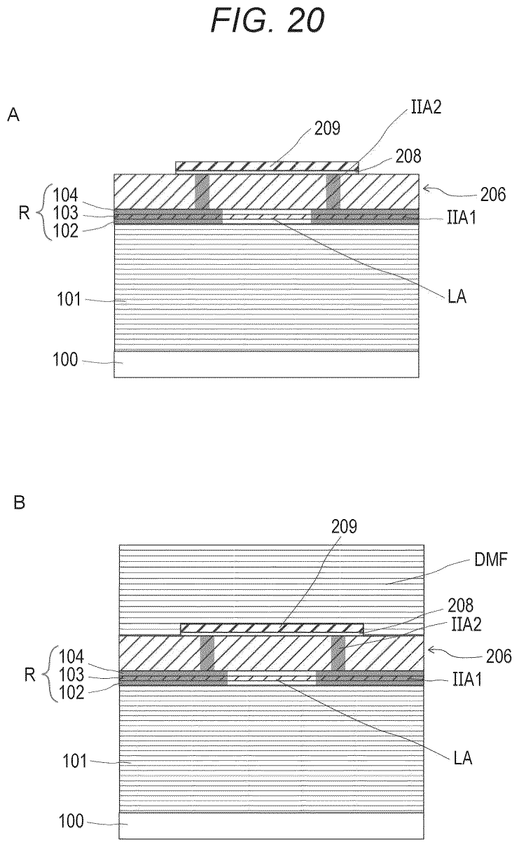

In the next step S26, the transparent conductive film 209 as a gate electrode is formed on the gate insulating film 208 (see FIG. 20A).

Specifically, the transparent conductive film 209 is formed on the gate insulating film 208 by a lift-off method using a photoresist.

More specifically, first, a resist is applied to a portion other than the gate insulating film 208. Next, a transparent conductive film is formed on the entire surface by vapor deposition or sputtering. Next, the resist and the transparent conductive film covering portions other than the gate insulating film 208 are removed. As a result, the transparent conductive film 209 is formed on the gate insulating film 208.

In the next step S27, a dielectric multilayer film reflector as the second multilayer film reflector 205 is formed on the transparent conductive film 209.

Specifically, first, the dielectric multilayer film DMF is formed on the entire surface (see FIG. 20B).

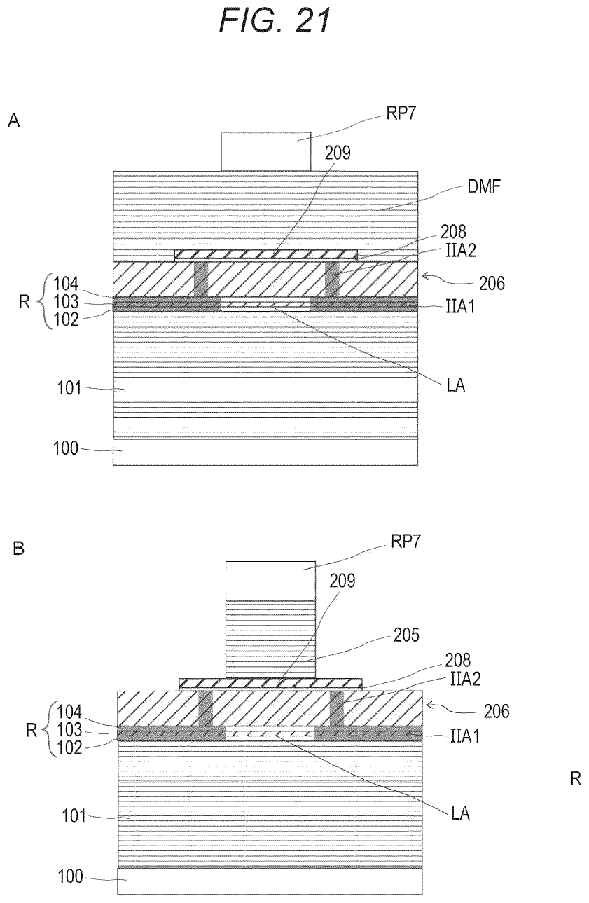

Next, a resist pattern RP7 is formed on a region of the dielectric multilayer film DMF where the second multilayer film reflector 205 is to be formed (see FIG. 21A).

Next, using the resist pattern RP7 as a mask, the dielectric multilayer film DMF is etched so that a part (for example, an outer peripheral portion) of the transparent conductive film 209 is exposed to form, for example, a cylindrical dielectric multilayer film reflector (see FIG. 21B).

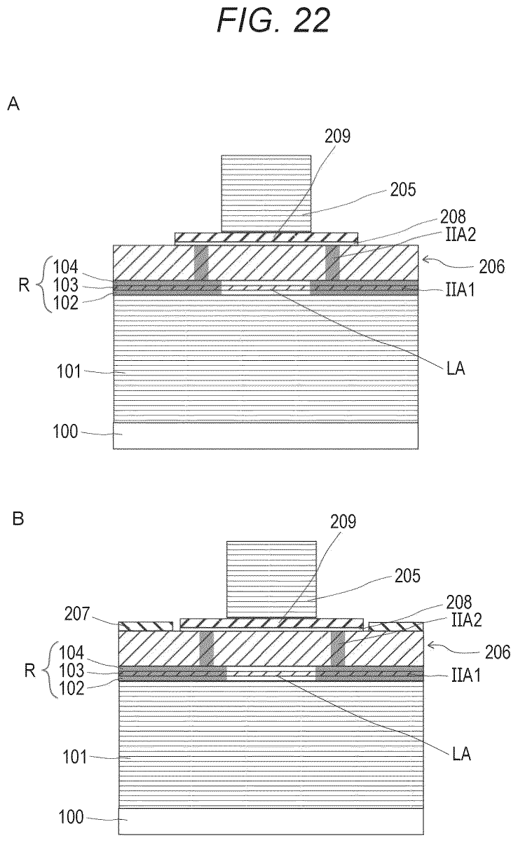

Finally, the resist pattern RP7 is removed (see FIG. 22A).

In the next step S28, the second electrode 207 is formed on the source region 206S (see FIG. 22B). The second electrode 207 is substantially the same as the second electrode 107 described above.

Specifically, the second electrode 207 is formed by a lift-off method using a photoresist.

More specifically, first, a resist is applied to a portion other than a portion where the second electrode 207 is to be formed, and an electrode material (for example, Ti/Pt/Au) is formed on the entire surface by vacuum deposition or sputtering. Next, electrode materials other than the electrode material to be the second electrode 207 are removed together with the resist. As a result, only the electrode material of the second electrode 207 remains on the source region 206S.

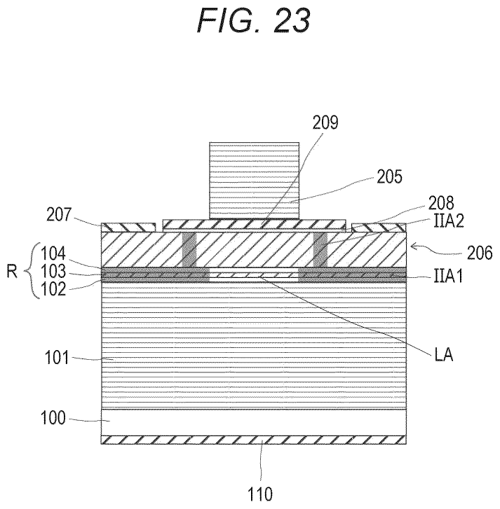

In the next step S29, the first electrode 110 is formed on the back surface of the substrate 100 (see FIG. 23). Specifically, an electrode material (for example, AuGe/Ni/Au) is solidly formed on the back surface of the substrate 100 by vacuum deposition or sputtering.

Thereafter, processing such as annealing is performed to form a plurality of surface emitting laser elements 20 on one wafer. Thereafter, the plurality of surface emitting laser elements 20 is separated for each element by dicing to obtain a plurality of chip-shaped surface emitting laser elements 20.

Alternatively, processing such as annealing is performed to form a plurality of surface emitting laser arrays including the plurality of surface emitting laser elements 20 on one wafer. Thereafter, the plurality of surface emitting laser arrays is separated for each array by dicing to obtain a plurality of chip-shaped surface emitting laser arrays.

### (4) Effects of Surface Emitting Laser Element and Method for Manufacturing Surface Emitting Laser Element

Hereinafter, effects of the surface emitting laser element 20 and the method for manufacturing the surface emitting laser element 20 will be described.

In the surface emitting laser element 20 according to the second embodiment, the second structure ST2 further includes the semiconductor layer 206 disposed between the second multilayer film reflector 205 and the resonator R, the drain region 206D is a region corresponding to the light emitting region LA of the semiconductor layer 206, and the source region 206S is a region around the drain region 206D of the semiconductor layer 206.

The second ion implantation region IIA2 is provided between the drain region 206D and the source region 206S in the semiconductor layer 206. Thus, the drain region 206D and the source region 206S can be simultaneously formed by one ion implantation.

The second ion implantation region IIA2 is provided in the entire region in the thickness direction of the semiconductor layer 206. As a result, energization between the drain region 206D and the source region 206S can be reliably inhibited.

The second structure ST2 further includes a transparent conductive film 209 in which a part corresponding to the light emitting region LA is disposed between the second multilayer film reflector 205 and the semiconductor layer 206 and the other part is exposed. As a result, the transparent conductive film 209 can function as a gate electrode that can be disposed between the first and second multilayer film reflectors 101 and 205 without interfering with the optical waveguide.

The method for manufacturing the surface emitting laser element 20 includes a step of laminating the first multilayer film reflector 101 and the resonator R including the active layer 103 in this order on the substrate 100, and a step of forming a structure including the second multilayer film reflector 205 on the resonator R. In the step of forming the structure, a MOSFET is formed as an example of a field effect transistor having a drain region 206D at a position of the active layer 103 corresponding to a light emitting region LA which is a region surrounded by the first ion implantation region IIA1 as a carrier confinement portion, and having a source region 206S at a position corresponding to a periphery of the light emitting region LA.

The step of forming the above structure includes a step of laminating the semiconductor layer SL on the resonator R, a step of forming the drain region 206D and the source region 206S by implanting ions into the semiconductor layer SL, a step of forming the transparent conductive film 209 on the semiconductor layer SL, and a step of forming the second multilayer film reflector 205 on the transparent conductive film 209. As a result, the MOSFET can be efficiently formed between the first and second multilayer film reflectors 101 and 205.

### <4. Surface Emitting Laser Element According to Third Embodiment of Present Technology>

### (1) Configuration of Surface Emitting Laser Element

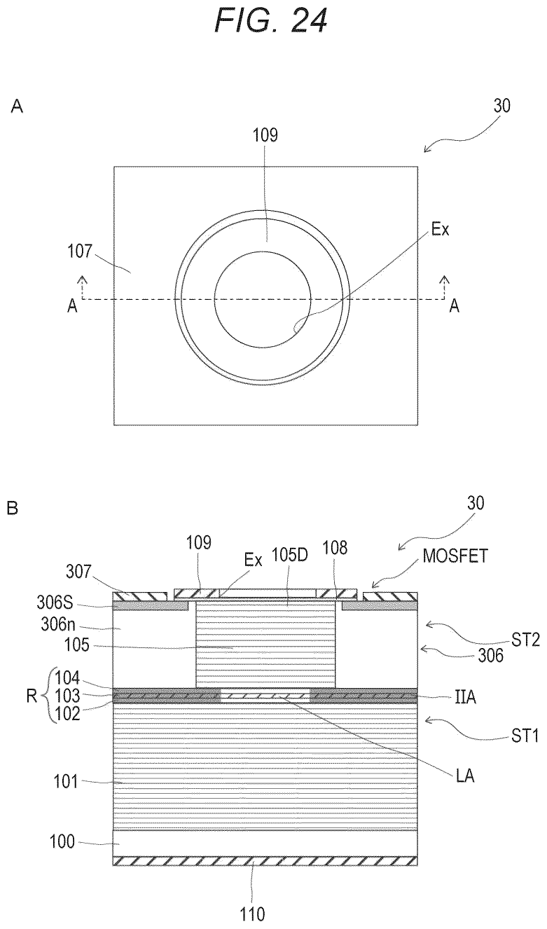

Hereinafter, a configuration of a surface emitting laser element according to a third embodiment of the present technology will be described with reference to FIGS. 24A and 24B. FIG. 24A is a plan view of a surface emitting laser according to the third embodiment of the present technology. FIG. 24B is a cross-sectional view of a surface emitting laser according to the third embodiment of the present technology. More specifically, FIG. 24B is a cross-sectional view taken along line A-A of FIG. 24A.

In the surface emitting laser element 30 according to the third embodiment, as illustrated in FIG. 24B, the second structure ST2 further includes the semiconductor layer 306 having the semiconductor region 306n having a conductivity type different from that of the second multilayer film reflector, disposed on the side opposite to the first multilayer film reflector 101 side of the resonator R and around the second multilayer film reflector 105, the drain region 105D is at least a part (for example, an upper portion) of the second multilayer film reflector 105, and the source region 306S is an impurity region provided in the semiconductor layer 306. The impurity region contains impurities such as Zn, for example.

More specifically, in the surface emitting laser element 30, as an example, the semiconductor layer 306 having the n-type semiconductor region 306n and the source region 306S is provided so as to surround the second multilayer film reflector 105 having the drain region 105D. A region (for example, an upper portion) of the second multilayer film reflector 105 surrounded by the source region 306S is the drain region 105D.

That is, the source region 306S is provided on the semiconductor layer 306 as an example. The n-type semiconductor region 306n is interposed between the source region 306S and the second multilayer film reflector 105 including the drain region 105D.

Further, in the surface emitting laser element 30, the gate insulating film 108 is disposed between the gate electrode 109 in which the emission port Ex is formed and the second multilayer film reflector 105.

### (2) Operation of Surface Emitting Laser Element

Hereinafter, the operation of the surface emitting laser element 30 will be described.

For driving the surface emitting laser element 30, the first power supply V1 for generating the current injected into the light emitting region LA and the second power supply V2 for driving the MOSFET are used.

In the surface emitting laser element 30, as an example, the first electrode 110 is connected to the cathode of the first power supply V1 in advance, and the second electrode 307 (substantially the same as the second electrode 107) is connected to the anode of the first power supply V1. That is, in the surface emitting laser element 30, the voltage (driving voltage) of the first power supply V1 is applied between the first and second electrodes 110 and 307 during standby.

In the surface emitting laser element 30, as an example, at the time of driving, the anode of the second power supply V2 is further connected to the second electrode 307, the cathode of the second power supply V2 is connected to the gate electrode 109, and the voltage (gate voltage) of the second power supply V2 is applied between the gate electrode 109 and the second electrode 307. At this time, a channel is formed between the source region 306S and the drain region 105D, and a current flows from the source region 306S to the drain region 105D. The current flowing to the drain region 105D passes through the second multilayer film reflector 105 and the second cladding layer 104, and is injected into the light emitting region LA of the active layer 103 while being narrowed by the ion implantation region IIA. At this time, the light emitting region LA emits light, and the light reciprocates between the first and second multilayer film reflectors 101 and 105 while being amplified by the active layer 103, and is emitted as laser light from the emission port Ex when the oscillation condition is satisfied. The current injected into the light emitting region LA reaches the first electrode 110 via the first cladding layer 102, the first multilayer film reflector 101, and the substrate 100, and flows out from the first electrode 110 to the cathode of the first power supply V1.

In the surface emitting laser element 30, when the application of the gate voltage is released (when the driving of the MOSFET is stopped), a channel is not formed between the source region 306S and the drain region 105D, and a current does not flow from the source region 306S to the drain region 105D.

As described above, the surface emitting laser element 30 can control the injection of the current to the light emitting region LA by applying/releasing the gate voltage of the MOSFET (can switch on/off of the energization to the light emitting region LA).

### (3) Method for Manufacturing Surface Emitting Laser Element

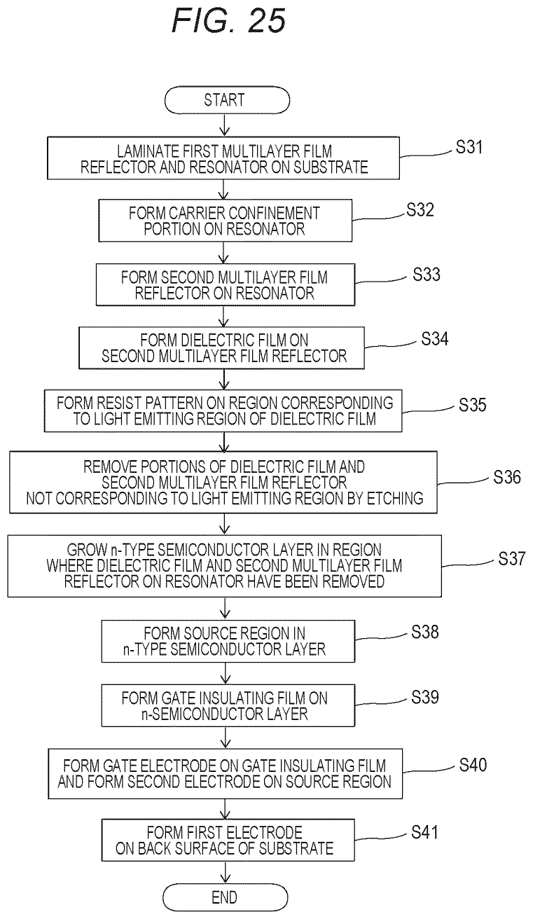

Hereinafter, a method for manufacturing the surface emitting laser element 30 will be described with reference to the flowchart of FIG. 25, and cross-sectional views of FIGS. 5A to 6B and FIGS. 26A to 33B.

Here, as an example, a plurality of surface emitting laser elements 30 is simultaneously generated on one wafer which is a base material of the substrate 100 by a semiconductor manufacturing method using a semiconductor manufacturing apparatus. Next, the plurality of continuous and integrated surface emitting laser elements 30 is separated from each other by dicing to obtain a plurality of chip-shaped surface emitting laser elements 30.

Alternatively, as an example, a plurality of surface emitting laser arrays in which a plurality of surface emitting laser elements 30 is arranged in an array on one wafer which is a base material of the substrate 100 is simultaneously generated, and a plurality of continuous and integrated surface emitting laser arrays is separated from each other by dicing to obtain a plurality of chip-shaped surface emitting laser arrays.

In the first step S31, the first multilayer film reflector 101 and the resonator R are laminated on the substrate 100. Specifically, the first multilayer film reflector 101, the first cladding layer 102, the active layer 103, and the second cladding layer 104 are laminated in this order on the substrate 100 using a chemical vapor deposition (CVD) method, for example, a metal organic chemical vapor deposition (MOCVD) method (see FIG. 5A).

In the next step S32, the ion implantation region IIA as the carrier confinement portion is formed on the resonator R.

Specifically, first, a resist pattern RP1 is formed on a region corresponding to the light emitting region LA of the resonator R (see FIG. 5B).

Next, for example, B ions are implanted into the resonator R using the resist pattern RP1 as a mask to form an ion implantation region IIA surrounding a region corresponding to the light emitting region LA of the resonator R (see FIG. 6A).

Finally, the resist pattern RP1 is removed (see FIG. 6B).

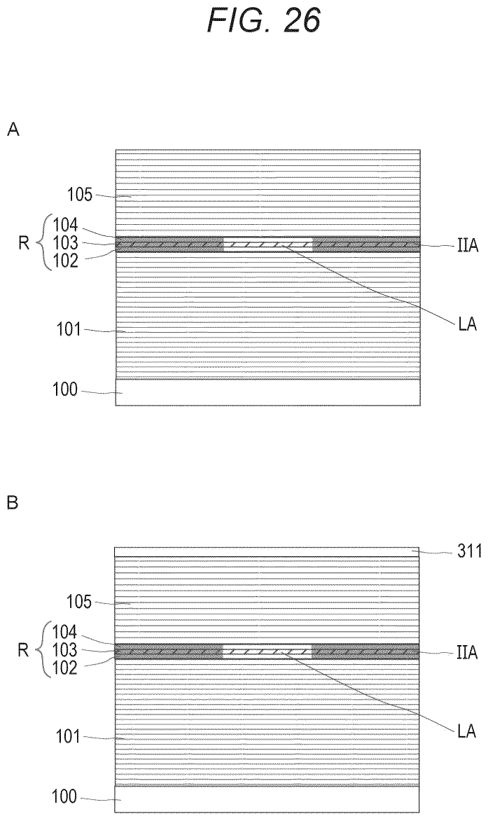

In the next step S33, the second multilayer film reflector 105 is formed on the resonator R (see FIG. 26A).

Specifically, first, the second multilayer film reflector 105 is formed on the resonator R in which the ion implantation region IIA is formed by regrowth (see FIG. 26A).

In the next step S34, the dielectric film 311 (for example, SiO₂ film) is formed on the second multilayer film reflector 105 (see FIG. 26B).

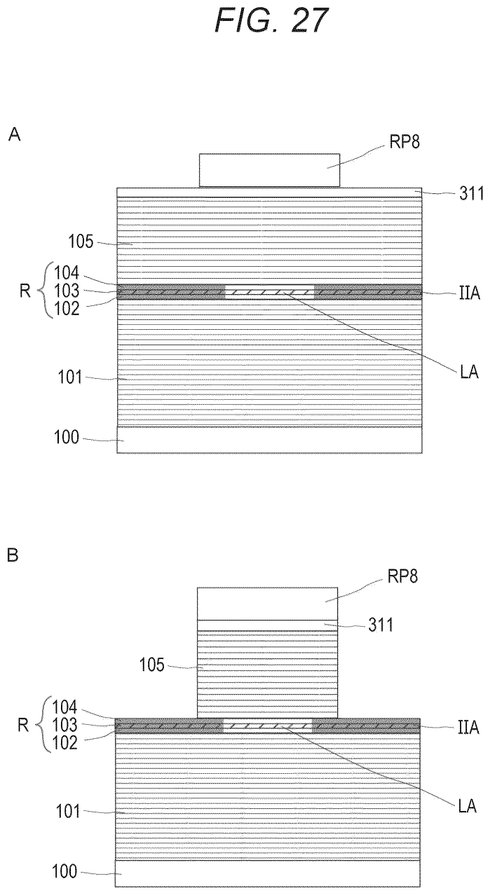

In the next step S35, a resist pattern RP8 is formed on a region corresponding to the light emitting region LA of the dielectric film 311 (see FIG. 27A).

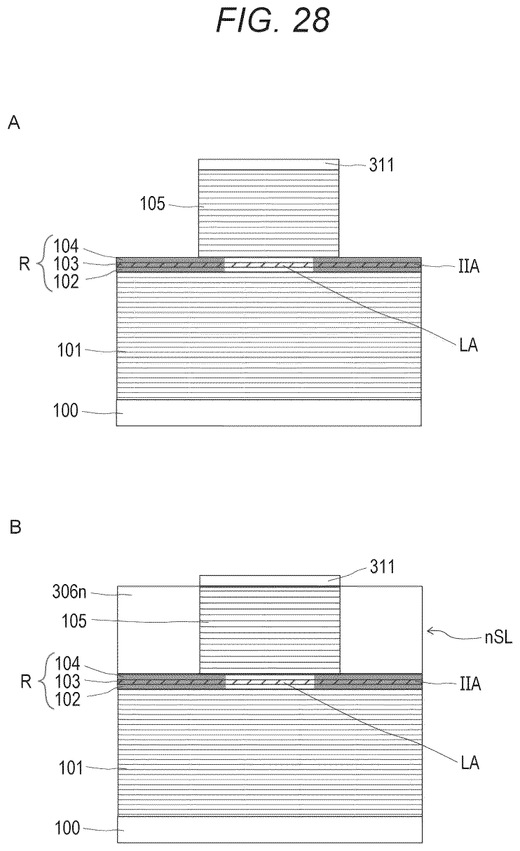

In the next step S36, portions of the dielectric film 311 and the second multilayer film reflector 105 not corresponding to the light emitting region LA are removed by etching using the resist pattern RP8 as a mask (see FIG. 27B). As a result, the second multilayer film reflector 105 is molded in a substantially cylindrical shape. The etching depth at this time is preferably as deep as possible in order to enhance the effect of current confinement in the light emitting region LA, but for example, if the etching depth is several tens to several hundred nm, desired characteristics can be obtained. Here, etching was performed until the resonator R was exposed. Thereafter, the resist pattern RP8 is removed (see FIG. 28A).

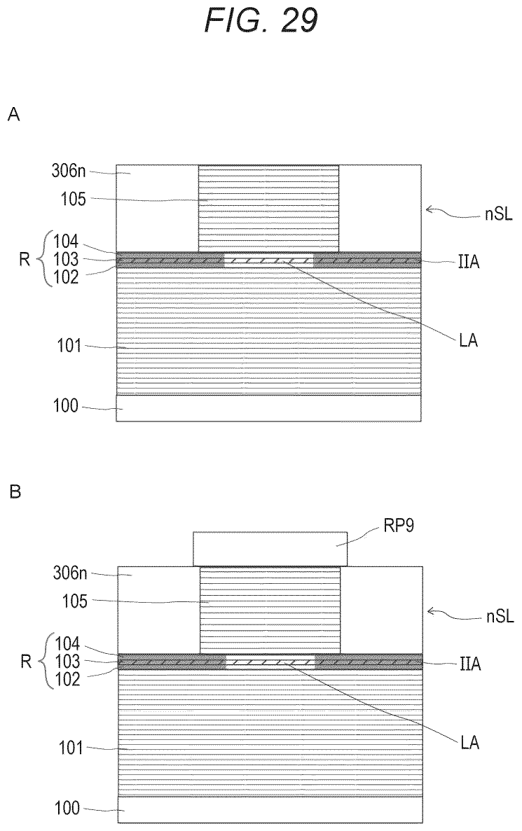

In the next step S37, the n-type semiconductor layer nSL is grown in the region where the dielectric film 311 and the second multilayer film reflector 105 on the resonator R have been removed (see FIG. 28B). At this time, since the regrowth is inhibited by the dielectric film 311 on the second multilayer film reflector 105, the n-type semiconductor layer nSL is grown to substantially the same height as the height of the upper surface of the second multilayer film reflector 105. Thereafter, the dielectric film 311 on the second multilayer film reflector 105 is removed by etching (see FIG. 29A).

In the next step S38, the source region 306S is formed in the n-type semiconductor layer nSL.

Specifically, first, a resist pattern RP9 is formed in a region of the second multilayer film reflector 105 and the n-type semiconductor layer nSL not corresponding to the source region 306S (see FIG. 29B).

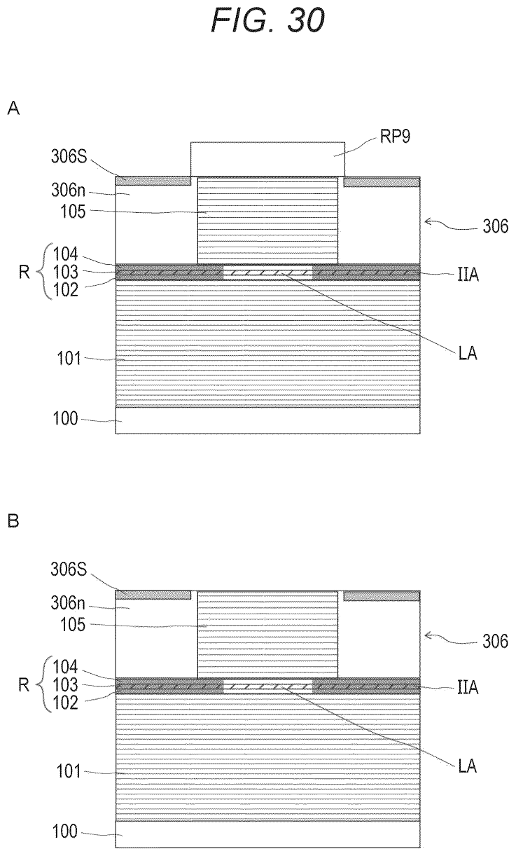

Next, using the resist pattern RP9 as a mask, Zn is vapor-phase diffused while being heated at, for example, 550° C. to form the source region 306S in the n-type semiconductor layer nSL (see FIG. 30A). At this time, Zn is diffused only in a part (for example, an upper portion) of the n-type semiconductor layer nSL in the thickness direction. As a result, the source region 306S surrounding the drain region 105D is formed, the source region 306S being separated from both the drain region 105D and the second multilayer film reflector 105 by the n-type semiconductor region 306n.

Finally, the resist pattern RP9 is removed (see FIG. 30B).

In the next step S39, the gate insulating film 108 is formed on the semiconductor layer 306.

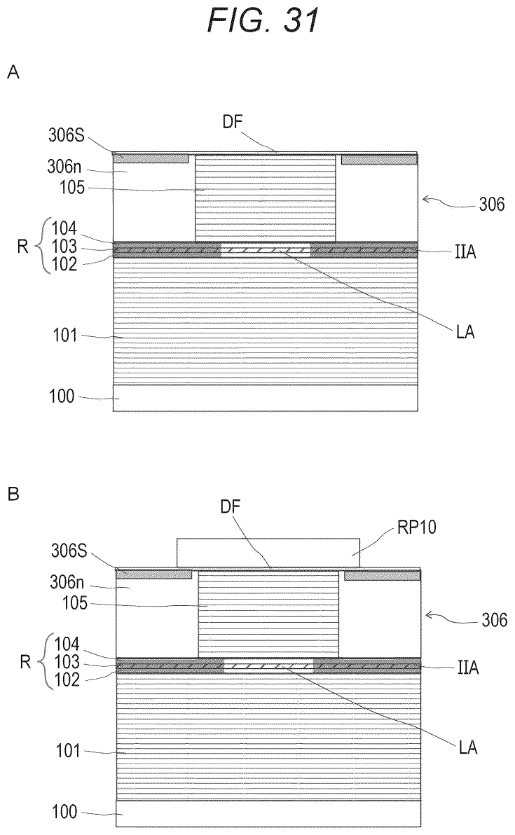

Specifically, first, the dielectric film DF to be the gate insulating film 108 is formed on the second multilayer film reflector 105 having the drain region 105D and the semiconductor layer 306 having the source region 306S (FIG. 31A).

Next, a resist pattern RP10 is formed on a region of the dielectric film DF corresponding to the inner peripheral portions of the drain region 105D and the source region 306S (see FIG. 31B).

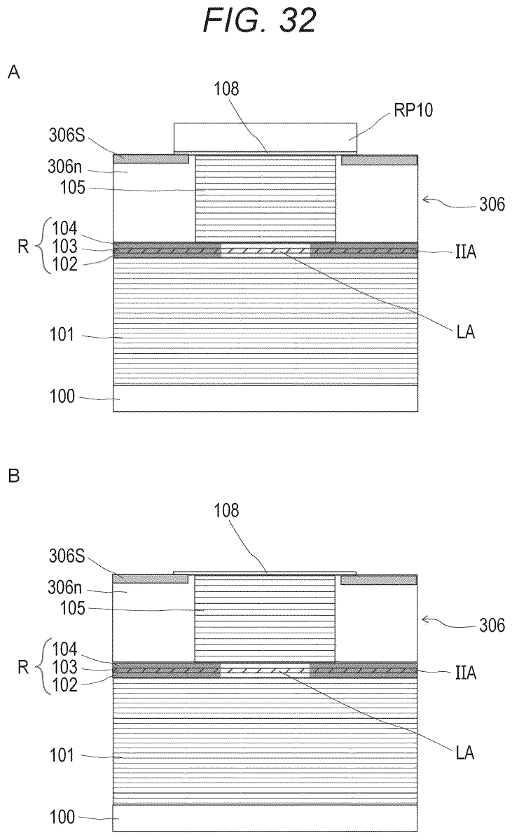

Next, the dielectric film DF is etched using the resist pattern RP10 as a mask to form the gate insulating film 108 (see FIG. 32A).

Finally, the resist pattern RP10 is removed (see FIG. 32B).

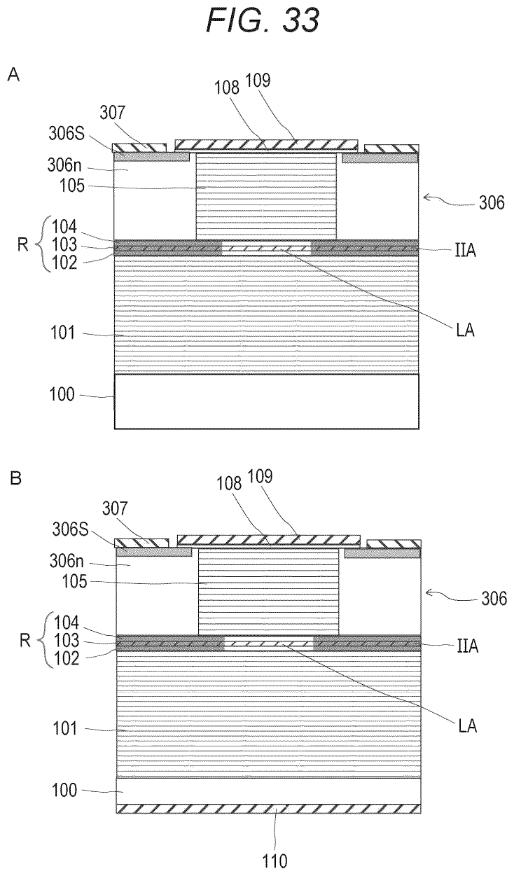

In the next step S40, the gate electrode 109 is formed on the gate insulating film 108, and the second electrode 307 is formed on the source region 306S (see FIG. 33A).

Specifically, the gate electrode 109 and the second electrode 307 are formed by a lift-off method using a photoresist.

More specifically, first, a resist is applied to a portion other than a portion where the gate electrode 109 and the second electrode 307 are to be formed, and an electrode material (for example, Ti/Pt/Au) is formed on the entire surface by vacuum deposition or sputtering. Next, electrode materials other than the electrode materials to be the gate electrode 109 and the second electrode 307 are removed together with the resist. As a result, only the electrode materials of the gate electrode 109 and the second electrode 307 remain.

In the final step S41, the first electrode 110 is formed on the back surface of the substrate 100 (see FIG. 33B). Specifically, an electrode material (for example, AuGe/Ni/Au) is solidly formed on the back surface of the substrate 100 by vacuum deposition or sputtering.

Thereafter, processing such as annealing is performed to form a plurality of surface emitting laser elements 30 on one wafer. Thereafter, the plurality of surface emitting laser elements 30 is separated for each element by dicing to obtain a plurality of chip-shaped surface emitting laser elements 30.

Alternatively, processing such as annealing is performed to form a plurality of surface emitting laser arrays including the plurality of surface emitting laser elements 30 on one wafer. Thereafter, the plurality of surface emitting laser arrays is separated for each array by dicing to obtain a plurality of chip-shaped surface emitting laser arrays.

### (4) Effects of Surface Emitting Laser Element and Method for Manufacturing Surface Emitting Laser Element

Hereinafter, effects of the surface emitting laser element 30 and the method for manufacturing the surface emitting laser element 30 will be described.

In the surface emitting laser element 30, the second structure ST2 including the second multilayer film reflector 105 further includes the semiconductor layer 306 having the n-type semiconductor region 306n arranged on the side opposite to the first multilayer film reflector 101 side of the resonator R and around the second multilayer film reflector 105, the drain region 105D is at least a part (for example, an upper portion) of the second multilayer film reflector 105, and the source region 306S is an impurity region provided in the semiconductor layer 306. As a result, it is possible to provide the surface emitting laser element 30 in which the second multilayer film reflector 105 also functions as a drain region. In addition, in a case where the refractive index of the n-type semiconductor region 306n is lower than the refractive index of the second multilayer film reflector 105, the n-type semiconductor region 306n functions as an optical confinement portion.

The surface emitting laser element 30 includes a step of laminating a first multilayer film reflector 101 and a resonator R including an active layer 103 in this order on a substrate 100, and a step of forming a structure including a second multilayer film reflector 105 on the resonator R. In the step of forming the structure, a MOSFET is formed as an example of a field effect transistor having a drain region 105D at a position of the active layer 103 corresponding to a light emitting region LA that is a region surrounded by an ion implantation region IIA as a carrier confinement portion and having a source region 306S at a position corresponding to a periphery of the light emitting region LA.

The step of forming the above structure includes a step of laminating the second multilayer film reflector 105 on the resonator R, a step of removing a region of the second multilayer film reflector 105 corresponding to the periphery of the light emitting region LA by etching to form the drain region 105D, a step of laminating the n-type semiconductor layer nSL on the region of the resonator R from which the second multilayer film reflector 105 has been removed, and a step of diffusing impurities into the n-type semiconductor layer nSL to form the source region 306S. As a result, the surface emitting laser element 30 in which the second multilayer film reflector 105 also functions as a drain region can be efficiently manufactured.

### <5. Surface Emitting Laser Element According to Modifications 1 to 8 of First Embodiment of Present Technology>

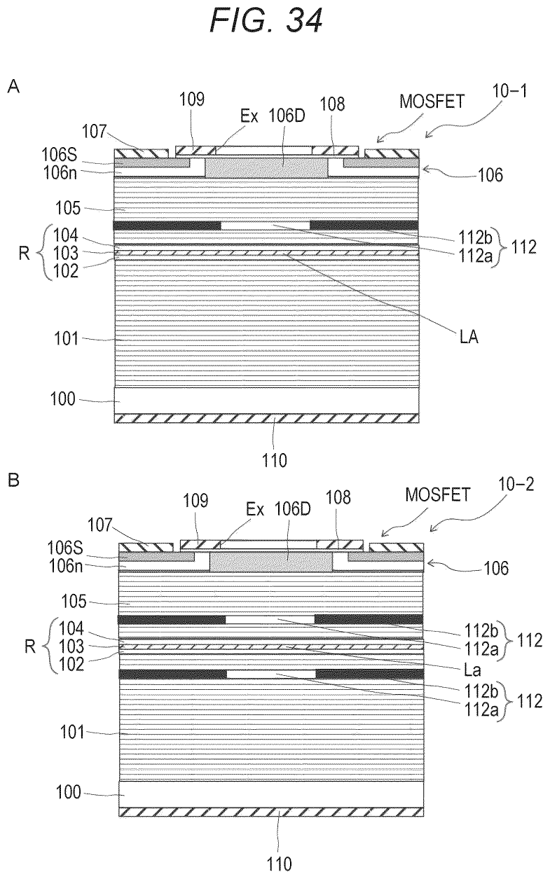

Hereinafter, a surface emitting laser element according to Modification 1 to 8 of the first embodiment will be described with reference to FIGS. 34A to 37B.

A surface emitting laser element 10-1 according to Modification 1 of the first embodiment illustrated in FIG. 34A includes an oxidation confinement layer 112 as an optical confinement portion and a current confinement portion in a second multilayer film reflector 105 in addition to the configuration (however, the ion implantation region IIA is excluded) of the surface emitting laser element 10 according to the first embodiment. The oxidation confinement layer 112 includes a non-oxidized region 112a constituted by AlAs and provided at a position corresponding to the light emitting region LA, and an oxidized region 112b constituted by an oxide of AlAs (for example, Al₂O₃) and surrounding the outer periphery of the non-oxidized region 112a.

In the surface emitting laser element 10-1, at the time of driving, the current flowing from the source electrode 106S to the drain electrode 106D is injected into the light emitting region LA while being narrowed by the oxidation confinement layer 112. At this time, the light emitting region LA emits light, and the light reciprocates between the first and second multilayer film reflectors 101 and 105 while being constricted by the oxidation confinement layer 112 and amplified by the active layer 103, and is emitted from the emission port Ex via the drain region 106D when the oscillation condition is satisfied.

According to the surface emitting laser element 10-1, since the oxidation confinement layer 112 as the optical confinement portion and the current confinement portion (carrier confinement portion) is provided, the light emission efficiency can be further improved.

A surface emitting laser element 10-2 according to Modification 2 of the first embodiment illustrated in FIG. 34B includes an oxidation confinement layer 112 as an optical confinement portion and a current confinement portion in the first multilayer film reflector 101 and the second multilayer film reflector 105, in addition to the configuration (however, the ion implantation region IIA is excluded) of the surface emitting laser element 10 according to the first embodiment.

According to the surface emitting laser element 10-2, since the oxidation confinement layer 112 as the optical confinement portion is provided on both sides of the resonator R, the light emission efficiency can be further improved.

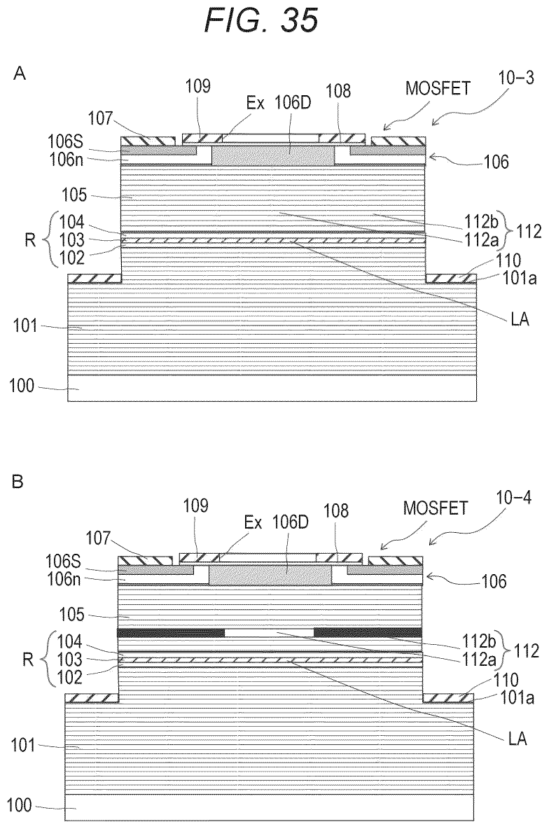

A surface emitting laser element 10-3 according to Modification 3 of the first embodiment illustrated in FIG. 35A has a configuration substantially similar to the surface emitting laser element 10 according to the first embodiment except that the first electrode 110 is provided on the first multilayer film reflector 101. In the surface emitting laser element 10-3, a step portion 101a having a frame shape (for example, an annular shape) in plan view is formed in the first multilayer film reflector 101, and a first electrode 110 having a frame shape (for example, an annular shape) in plan view is formed in the step portion 101a.

The step portion 101a is formed by laminating the first multilayer film reflector 101, the resonator R, the second multilayer film reflector 105, and the n-type semiconductor layer nSL on the substrate 100, and then etching the peripheral portions of the upper portions of the n-type semiconductor layer nSL, the second multilayer film reflector 105, the resonator R, and the first multilayer film reflector 101.

A surface emitting laser element 10-4 according to Modification 4 of the first embodiment illustrated in FIG. 35B has a configuration similar to the surface emitting laser element 10-3 illustrated in FIG. 35A except that an oxidation confinement layer 112 is provided in the second multilayer film reflector 105.

According to the surface emitting laser element 10-4, since the oxidation confinement layer 112 as the optical confinement portion and the current confinement portion (carrier confinement portion) is provided, the light emission efficiency can be further improved.

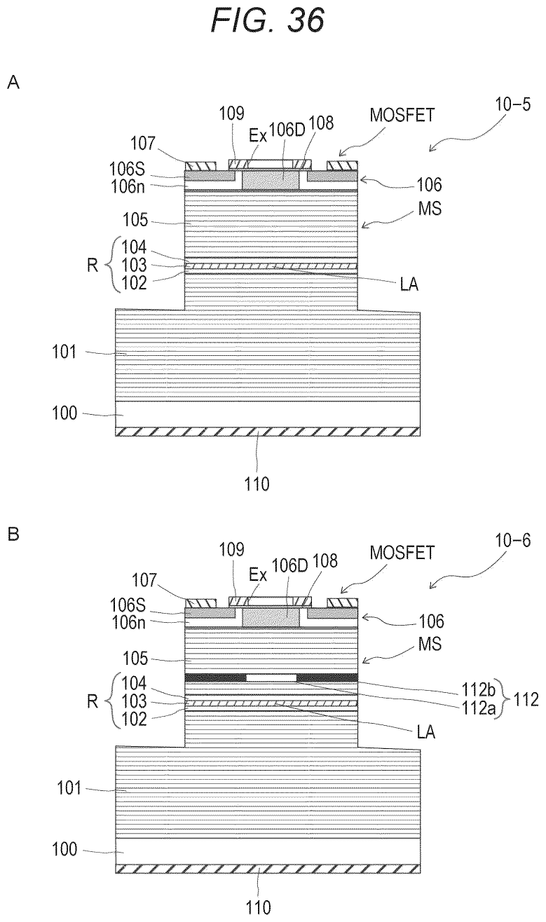

A surface emitting laser element 10-5 according to Modification 5 of the first embodiment illustrated in FIG. 36A has a configuration similar to the surface emitting laser element 10 according to the first embodiment except that the surface emitting laser element 10-5 has a mesa structure MS including a semiconductor layer 106, a second multilayer film reflector 105, a resonator R, and an upper portion of the first multilayer film reflector 101.

According to the surface emitting laser element 10-5, the effect of confining light and current can be obtained by the mesa structure MS, and the light emission efficiency can be improved.

A surface emitting laser element 10-6 according to Modification 6 of the first embodiment illustrated in FIG. 36B has a configuration similar to the surface emitting laser element 10-5 illustrated in FIG. 36A except that an oxidation confinement layer 112 is provided in the second multilayer film reflector 105.

According to the surface emitting laser element 10-6, since the oxidation confinement layer 112 as the optical confinement portion and the current confinement portion (carrier confinement portion) is provided, the light emission efficiency can be further improved.

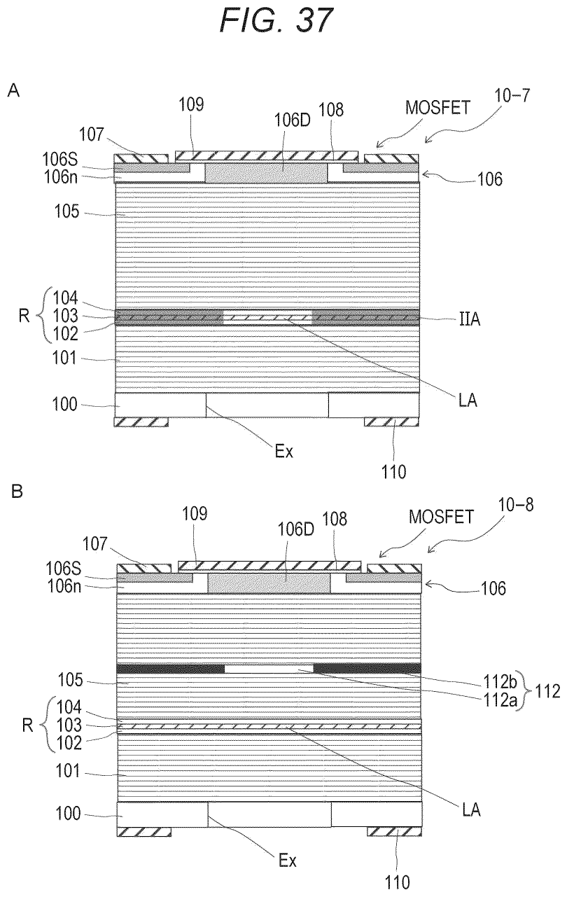

A surface emitting laser element 10-7 according to Modification 7 of the first embodiment illustrated in FIG. 37A is a back surface emitting type surface emitting laser element that emits laser light to the back surface side of the substrate 100. In the surface emitting laser element 10-7, instead of the gate electrode 109, an opening as the emission port Ex is formed in a region corresponding to the light emitting region LA of the substrate 100. In the surface emitting laser element 10-7, the reflectance of the second multilayer film reflector 105 is set higher than the reflectance of the first multilayer film reflector 101.

A surface emitting laser element 10-8 according to Modification 8 of the first embodiment illustrated in FIG. 37B has a configuration similar to the surface emitting laser element 10-7 illustrated in FIG. 37A except that an oxidation confinement layer 112 is provided in the second multilayer film reflector 105.

According to the surface emitting laser element 10-8, since the oxidation confinement layer 112 as the optical confinement portion and the current confinement portion (carrier confinement portion) is provided, the light emission efficiency can be further improved.

### <6. Surface Emitting Laser Element According to Modifications 1 to 10 of Second Embodiment of Present Technology>

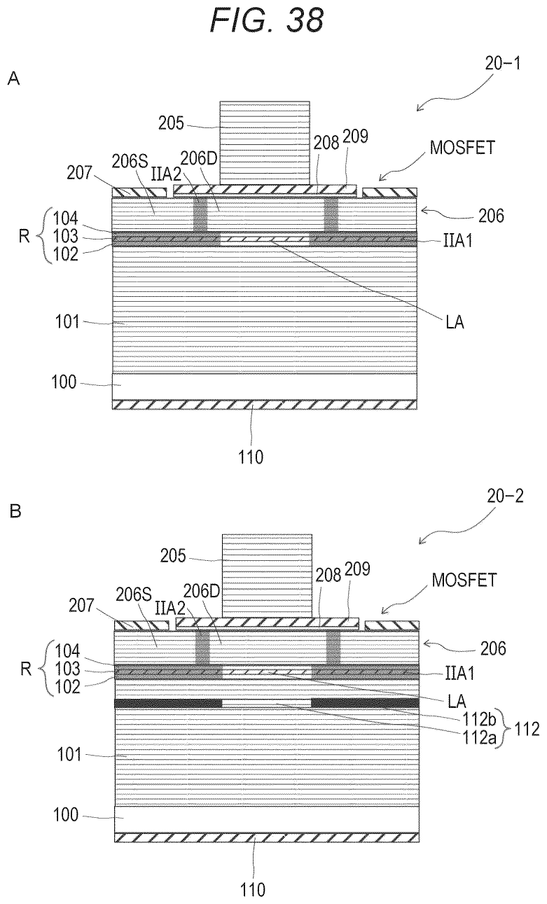

Hereinafter, a surface emitting laser element according to Modification 1 to 10 of the second embodiment will be described with reference to FIGS. 38A to 42B.

A surface emitting laser element 20-1 according to Modification 1 of the second embodiment illustrated in FIG. 38A has a configuration similar to the surface emitting laser element 20 according to the second embodiment except that the semiconductor layer 206 is a p-type semiconductor multilayer film reflector. The semiconductor multilayer film reflector has a structure in which a high refractive index layer and a low refractive index layer are alternately laminated with an optical thickness of ¼ (λ/4) of the oscillation wavelength A. Each refractive index layer is constituted by, for example, a p-type AlGaAs-based compound semiconductor. In the surface emitting laser element 20-1, the reflectance of the reflector including the second multilayer film reflector 205 and the semiconductor layer 206 (semiconductor multilayer film reflector) is set to be lower than the reflectance of the first multilayer film reflector 101.

In the semiconductor multilayer film reflector, a drain region 206D is provided in a region corresponding to the light emitting region LA, and a source region 206S is provided in a region surrounding the drain region 206D.

According to the surface emitting laser element 20-1, since the semiconductor multilayer film reflector is provided between the resonator R and the second multilayer film reflector 205, the reflectance can be sufficiently increased even if the number of pairs of dielectric films constituting the dielectric multilayer film reflector as the second multilayer film reflector 205 is reduced.

A surface emitting laser element 20-2 according to Modification 2 of the second embodiment illustrated in FIG. 38B has a configuration similar to the surface emitting laser element 20-1 illustrated in FIG. 38A except that an oxidation confinement layer 112 is provided in the first multilayer film reflector 101.

According to the surface emitting laser element 20-2, the light emission efficiency can be further improved.

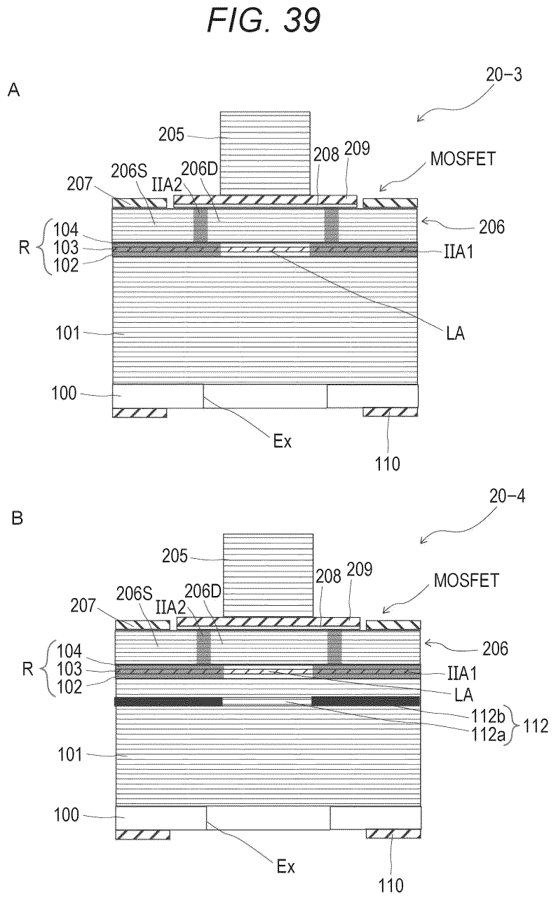

A surface emitting laser element 20-3 according to Modification 3 of the second embodiment illustrated in FIG. 39A has a configuration substantially similar to the surface emitting laser element 20-1 according to Modification 1 except that the surface emitting laser element 20-3 is a back surface emitting type surface emitting laser element. In the surface emitting laser element 20-3, an opening as the emission port Ex is formed in a region corresponding to the light emitting region LA of the substrate 100. In the surface emitting laser element 20-3, the reflectance of the reflector including the second multilayer film reflector 205 and the semiconductor layer 206 (semiconductor multilayer film reflector) is set higher than the reflectance of the first multilayer film reflector 101.

A surface emitting laser element 20-4 according to Modification 4 of the second embodiment illustrated in FIG. 39B has a configuration similar to the surface emitting laser element 20-3 illustrated in FIG. 39A except that an oxidation confinement layer 112 is provided in the first multilayer film reflector 101.

According to the surface emitting laser element 20-4, the light emission efficiency can be further improved.

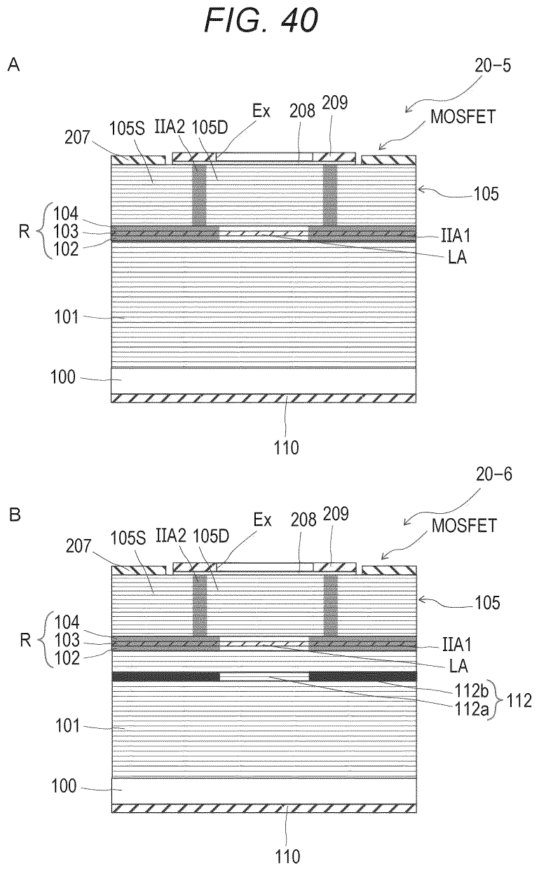

A surface emitting laser element 20-5 according to Modification 5 of the second embodiment illustrated in FIG. 40A has a configuration substantially similar to the surface emitting laser element 20 according to the second embodiment except that a second multilayer film reflector 105 is provided instead of the semiconductor layer 206 and the second multilayer film reflector 205.

In the surface emitting laser element 20-5, the second ion implantation region IIA2 is provided in the entire region in the thickness direction of the second multilayer film reflector 105. In the second multilayer film reflector 105, a region corresponding to the light emitting region LA is the drain region 105D, and a region surrounding the drain region 105D via the second ion implantation region IIA2 is the source region 106S.

According to the surface emitting laser element 20-5, the layer configuration can be simplified, and the number of manufacturing steps can be reduced.

A surface emitting laser element 20-6 according to Modification 6 of the second embodiment illustrated in FIG. 40B has a configuration similar to the surface emitting laser element 20-5 illustrated in FIG. 40A except that an oxidation confinement layer 112 is provided in the first multilayer film reflector 101.

According to the surface emitting laser element 20-6, the light emission efficiency can be further improved.

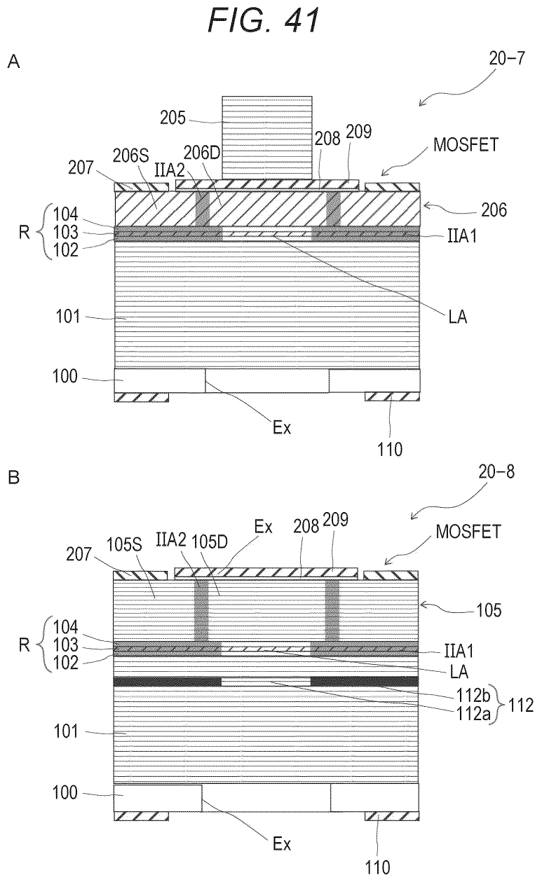

A surface emitting laser element 20-7 according to Modification 7 of the second embodiment illustrated in FIG. 41A has a configuration substantially similar to the surface emitting laser element 20 according to the second embodiment except that the surface emitting laser element 20-7 is a back surface emitting type surface emitting laser element. In the surface emitting laser element 20-7, an opening as the emission port Ex is formed in a region corresponding to the light emitting region LA of the substrate 100. In the surface emitting laser element 20-7, the reflectance of the second multilayer film reflector 205 is set higher than the reflectance of the first multilayer film reflector 101.

A surface emitting laser element 20-8 according to Modification 8 of the second embodiment illustrated in FIG. 41B has a configuration similar to the surface emitting laser element 20-7 illustrated in FIG. 41A except that an oxidation confinement layer 112 is provided in the first multilayer film reflector 101.

According to the surface emitting laser element 20-8, the light emission efficiency can be further improved.

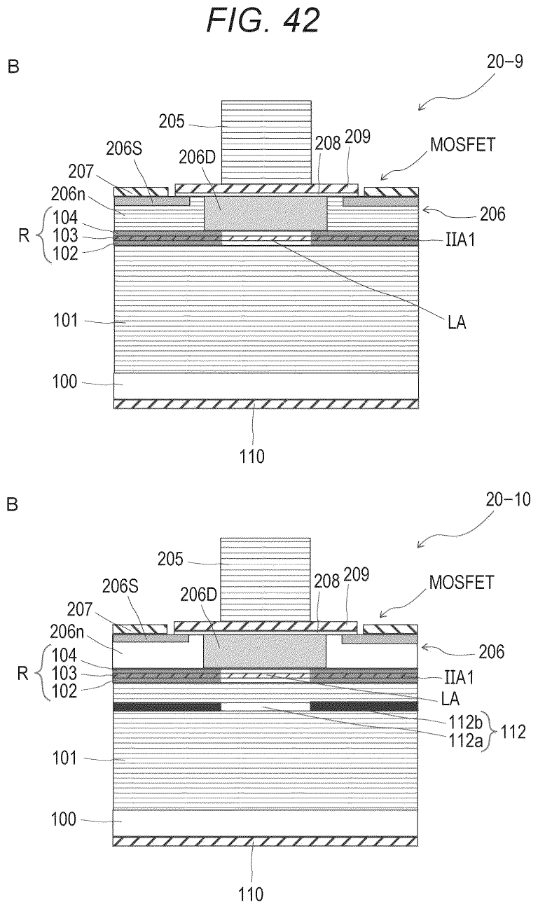

A surface emitting laser element 20-9 according to Modification 9 of the second embodiment illustrated in FIG. 42A has a configuration substantially similar to the surface emitting laser element 20-1 according to Modification 1 except that the second ion implantation region IIA2 is not provided, and the drain region 206D and the source region 206S are impurity regions provided in the semiconductor multilayer film reflector including the n-type semiconductor region 206n as the semiconductor layer 206.

A surface emitting laser element 20-10 according to Modification 10 of the second embodiment illustrated in FIG. 42B has a configuration substantially similar to the surface emitting laser element 20-1 according to Modification 1 except that the second ion implantation region IIA2 is not provided and the drain region 206D and the source region 206S are impurity regions provided in the semiconductor layer 206 including the n-type semiconductor region 206n.

### <7. Surface Emitting Laser Element According to Modifications 1 and 2 of Third Embodiment of Present Technology>

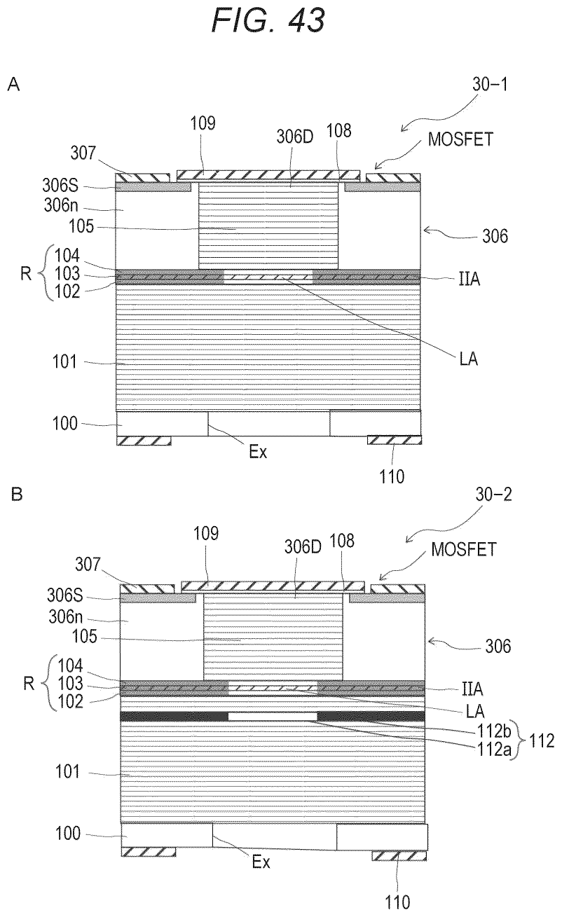

Hereinafter, a surface emitting laser element according to Modifications 1 and 2 of the third embodiment will be described with reference to FIGS. 43A and 43B.

A surface emitting laser element 30-1 according to Modification 1 of the third embodiment illustrated in FIG. 43A has a configuration substantially similar to the surface emitting laser element 30 according to the third embodiment except that the surface emitting laser element 30-1 is a back surface emitting type surface emitting laser element. In the surface emitting laser element 30-1, an opening as the emission port Ex is formed in a region corresponding to the light emitting region LA of the substrate 100. In the surface emitting laser element 20-1, the reflectance of the second multilayer film reflector 105 is set higher than the reflectance of the first multilayer film reflector 101.

A surface emitting laser element 30-2 according to Modification 2 of the third embodiment illustrated in FIG. 43B has a configuration similar to the surface emitting laser element 30-1 illustrated in FIG. 43A except that an oxidation confinement layer 112 is provided in the first multilayer film reflector 101.

According to the surface emitting laser element 30-2, the light emission efficiency can be further improved.

### <8. Light Source Device Including Surface Emitting Laser Element According to Present Technology>

A light source device 1 including a surface emitting laser element according to the present technology will be described with reference to FIGS. 44A and 44B. FIG. 44A is a diagram illustrating a standby state of the light source device 1, and FIG. 44B is a diagram illustrating a driving state of the light source device 1.

As illustrated in FIGS. 44A and 44B, the light source device 1 includes a surface emitting laser element (for example, surface emitting laser elements 10, 10-1 to 10-8, 20, 20-1 to 20-10, 30, 30-1, 30-2) according to the present technology, a first power supply V1 for generating a current injected into a light emitting region LA of the surface emitting laser element, and a second power supply V2 for driving a MOSFET as an example of a field effect transistor of the surface emitting laser element.

According to the light source device 1, since the load of the laser driver including the MOSFET is small, even a surface emitting laser element having a small light emitting area can be controlled by the Si-based laser driver.

### <9. Other Modifications of Present Technology>

The surface emitting laser element according to the present technology is not limited to the configuration described in each of the above embodiments and modifications, and can be appropriately changed.

In each of the above embodiments and modifications, the MOSFET has been described as an example of the field effect transistor included in the surface emitting laser element, but the present invention is not limited thereto, and for example, a junction FET in which a gate portion is a pn junction, and a metal-semiconductor FET in which a gate portion is a direct junction (Schottky junction) of a metal electrode and a semiconductor may be used.

In the surface emitting laser element of each of the above embodiments and modifications, as an example, an example in which the conductivity type is n-type on the substrate side and p-type on the front surface side has been described, but the conductivity type may be p-type on the substrate side and n-type on the front surface side.

Part of the configurations of the surface emitting laser elements of the above-described embodiments and modifications may be combined within a range not contradictory to each other.

In the embodiments and each modification described above, the material, conductivity type, thickness, width, length, shape, size, arrangement, and the like of each component constituting the surface emitting laser element can be appropriately changed within a range functioning as the surface emitting laser element.

### <10. Application Example to Electronic Device>

The technology according to the present disclosure (the present technology) can be applied to various products (electronic devices). For example, the technology according to the present disclosure may be implemented as an element mounted on any type of moving body such as an automobile, an electric vehicle, a hybrid electric vehicle, a motorcycle, a bicycle, a personal mobility, an airplane, a drone, a ship, a robot, and the like.

The surface emitting laser according to the present technology can also be applied as, for example, a light source of a device that forms or displays an image by laser light (for example, a laser printer, a laser copier, a projector, a head-mounted display, a head-up display, or the like).

### <11. Example in Which Surface Emitting Laser Is Applied to Distance Measuring Device>

Hereinafter, application examples of the surface emitting laser element according to each of the above-described embodiments and modifications will be described.

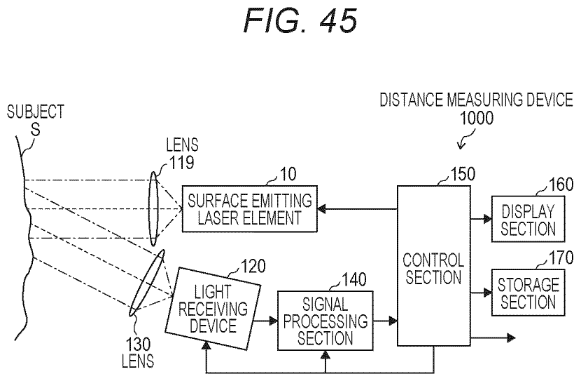

FIG. 45 illustrates an example of a schematic configuration of a distance measuring device 1000 including a surface emitting laser element 10 as an example of an electronic device according to the present technology. The distance measuring device 1000 measures the distance to a subject S by a time of flight (TOF) method. The distance measuring device 1000 includes the surface emitting laser element 10 as a light source. The distance measuring device 1000 includes, for example, a surface emitting laser element 10, a light receiving device 120, lenses 119 and 130, a signal processing section 140, a control section 150, a display section 160, and a storage section 170.

The light receiving device 120 detects light reflected by the subject S. The lens 119 is a lens for collimating the light emitted from the surface emitting laser element 10, and is a collimating lens. The lens 130 is a lens for condensing light reflected by the subject S and guiding the light to the light receiving device 120, and is a condenser lens.

The signal processing section 140 is a circuit for generating a signal corresponding to a difference between a signal input from the light receiving device 120 and a reference signal input from the control section 150. The control section 150 includes, for example, a time to digital converter (TDC). The reference signal may be a signal input from the control section 150, or may be an output signal of a detecting section that directly detects the output of the surface emitting laser element 10. The control section 150 is, for example, a processor that controls the surface emitting laser element 10, the light receiving device 120, the signal processing section 140, the display section 160, and the storage section 170. The control section 150 is a circuit that measures a distance to the subject S on the basis of a signal generated by the signal processing section 140. The control section 150 generates a video signal for displaying information about the distance to the subject S, and outputs the video signal to the display section 160. The display section 160 displays information about the distance to the subject S on the basis of the video signal input from the control section 150. The control section 150 stores information about the distance to the subject S in the storage section 170.

In the present application example, instead of the surface emitting laser element 10, any one of the above-described surface emitting laser elements 10-1 to 10-8, 20, 20-1 to 20-10, 30, 30-1, and 30-2 can be applied to the distance measuring device 1000.

<12. Example in which Distance Measuring Device is Mounted on Moving Body>

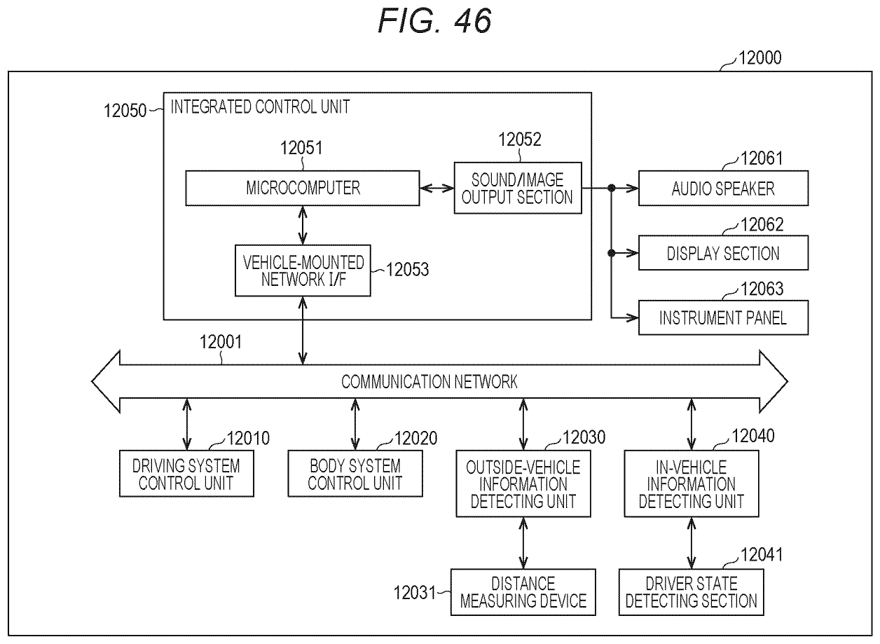

FIG. 46 is a block diagram illustrating a schematic configuration example of a vehicle control system which is an example of a moving body control system to which the technology according to the present disclosure can be applied.

The vehicle control system 12000 includes a plurality of electronic control units connected to each other via a communication network 12001. In the example illustrated in FIG. 46, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls operation of devices related to a drive system of a vehicle according to various programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle equipped with the vehicle control system 12000. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (subject S) outside the vehicle, and acquires distance data obtained by the measurement. The outside-vehicle information detecting unit 12030 may perform object detection processing of a person, a car, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041 may include, for example, a camera that images the driver, and, on the basis of detection information input from the driver state detecting section 12041, the in-vehicle information detecting unit 12040 may calculate a degree of fatigue or a degree of concentration of the driver, or may determine whether or not the driver is dozing off.

The microcomputer 12051 can calculate a control target value for the driving force generating device, the steering mechanism, or the braking device on the basis of the information about the inside or outside of the vehicle acquired by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS), the functions including collision avoidance or shock mitigation for the vehicle, follow-up traveling based on an inter-vehicle distance, vehicle speed maintaining traveling, vehicle collision warning, vehicle lane departure warning, and the like.

Furthermore, the microcomputer 12051 controls the driving force generating device, the steering mechanism, the braking device, or the like on the basis of the information around the vehicle acquired by the outside-vehicle information detecting unit 12030 or the in-vehicle information detecting unit 12040, thereby performing cooperative control for the purpose of automated driving or the like in which the vehicle autonomously travels without depending on the operation of the driver.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example of FIG. 46, an audio speaker 12061, a display section 12062, and an instrument panel 12063 are illustrated as the output device. The display section 12062 may, for example, include at least one of an on-board display or a head-up display.

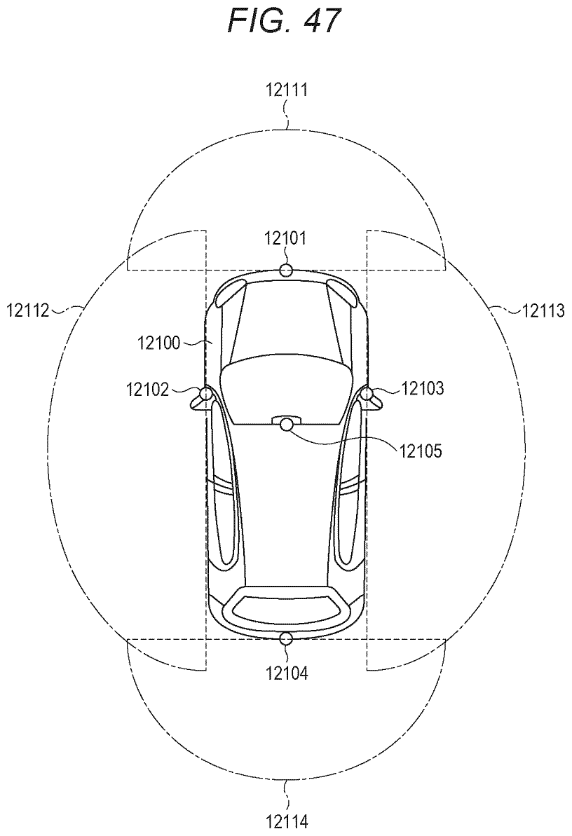

FIG. 47 is a diagram illustrating an example of an installation position of the distance measuring device 12031.

In FIG. 47, a vehicle 12100 includes distance measuring devices 12101, 12102, 12103, 12104, and 12105 as the distance measuring device 12031.

The distance measuring devices 12101, 12102, 12103, 12104, and 12105 are provided, for example, at positions such as a front nose, sideview mirrors, a rear bumper, a back door, and an upper portion of a windshield in a vehicle interior of the vehicle 12100. The distance measuring device 12101 provided on the front nose and the distance measuring device 12105 provided on the upper portion of the windshield in the vehicle cabin mainly acquire data of the front side of the vehicle 12100. The distance measuring devices 12102 and 12103 provided at the sideview mirrors mainly acquire data on the sides of the vehicle 12100. The distance measuring device 12104 provided on the rear bumper or the back door mainly acquires data behind the vehicle 12100. The data of the front acquired by the distance measuring devices 12101 and 12105 is mainly used for detecting a preceding vehicle, a pedestrian, an obstacle, a traffic light, a traffic sign, or the like.

Note that FIG. 47 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided on the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, on the basis of the distance data obtained from the distance measuring devices 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is higher than or equal to a set value and there is thus a possibility of collision, the microcomputer 12051 can output a warning to the driver via the audio speaker 12061 or the display section 12062 and perform forced deceleration or avoidance steering via the driving system control unit 12010 to perform driving assistance for collision avoidance.

An example of the moving body control system to which the technology according to the present disclosure can be applied has been described above. The technology according to the present disclosure can be applied to the distance measuring device 12031 among the configurations described above.

Furthermore, the present technology can also have the following configurations.

(1) A surface emitting laser element including:
a first structure including a first multilayer film reflector;
a second structure including a second multilayer film reflector; and
a resonator disposed between the first and second structures,
in which the resonator includes an active layer in which at least a light emitting region is disposed between the first and second multilayer film reflectors, and
the second structure is provided with a field effect transistor that controls injection of a current into the light emitting region.

(2) The surface emitting laser element according to (1), in which the field effect transistor includes: a drain region provided at a position of the second structure corresponding to the light emitting region; and a source region of the second structure provided around the drain region.

(3) The surface emitting laser element according to (2), in which an electrical resistance between the source region and the first multilayer film reflector is larger than an electrical resistance between the drain region and the first multilayer film reflector.

(4) The surface emitting laser element according to (2) or (3), in which the source region surrounds the drain region.

(5) The surface emitting laser element according to any one of (2) to (4), in which the field effect transistor includes: a gate electrode provided at a position of the second structure corresponding to the drain region and the source region; and a gate insulating film provided between the gate electrode and the drain region and the source region.

(6) The surface emitting laser element according to any one of (2) to (5), in which the field effect transistor includes: a source electrode provided at a position of the second structure in contact with the source region; and a drain electrode provided in the first structure.

(7) The surface emitting laser element according to any one of (2) to (6), in which the drain region and the source region are provided at a position of the second structure on a side opposite to a side of the active layer of the second multilayer film reflector.

(8) The surface emitting laser element according to any one of (2) to (7), in which the second structure further includes a semiconductor layer disposed on a surface of the second multilayer film reflector on a side opposite to the side of the active layer, and the semiconductor layer includes: a first impurity region as the drain region; a second impurity region as the source region; and a semiconductor region having a conductivity type different from a conductivity type of the drain region and the source region, at least a part of the semiconductor region being disposed between the first and second impurity regions.

(9) The surface emitting laser element according to (7) or (8), in which the drain region is in contact with the second multilayer film reflector, and the source region is not in contact with the second multilayer film reflector.

(10) The surface emitting laser element according to any one of (2) to (6), in which at least the drain region of the drain region and the source region is provided in the second multilayer film reflector.

(11) The surface emitting laser element according to (10), in which the drain region and the source region are provided in the second multilayer film reflector, and an ion implantation region is provided between the drain region and the source region in the second multilayer film reflector.

(12) The surface emitting laser element according to (11), in which the ion implantation region is provided in an entire region in a thickness direction of the second multilayer film reflector.

(13) The surface emitting laser element according to (2), in which the second structure further includes a semiconductor layer disposed between the second multilayer film reflector and the resonator, the drain region is a region corresponding to the light emitting region of the semiconductor layer, and the source region is a region around the drain region of the semiconductor layer.

(14) The surface emitting laser element according to (13), in which an ion implantation region is provided between the drain region and the source region in the semiconductor layer.

(15) The surface emitting laser element according to (14), in which the ion implantation region is provided in an entire region in a thickness direction of the semiconductor layer.

(16) The surface emitting laser element according to (13), in which the semiconductor layer includes: a first impurity region as the drain region; a second impurity region as the source region; and a semiconductor region having a conductivity type different from a conductivity type of the drain region and the source region, at least a part of the semiconductor region being disposed between the first and second impurity regions.

(17) The surface emitting laser element according to (13), in which the second structure further includes a transparent conductive film in which a part corresponding to the light emitting region is disposed between the second multilayer film reflector and the semiconductor layer and an other part is exposed.

(18) The surface emitting laser element according to (2), in which the second structure further includes a semiconductor layer disposed on a side opposite to a side of the first multilayer film reflector of the resonator and around the second multilayer film reflector, the drain region is at least a part of the second multilayer film reflector, and the semiconductor layer includes: an impurity region as the source region; and a semiconductor region having a conductivity type different from a conductivity type of the drain region and the source region, at least a part of the semiconductor region being disposed between the source region and the drain region.

(19) The surface emitting laser element according to any one of (1) to (18), in which at least one of the resonator, the first multilayer film reflector, or the second multilayer film reflector is provided with a carrier confinement portion.

(20) A light source device including:
a surface emitting laser element according to any one of (1) to (19),
a first power supply that generates a current to be injected into a light emitting region of the surface emitting laser element; and
a second power supply that drives a field effect transistor of the surface emitting laser element.

(21) A method for manufacturing a surface emitting laser element, the method including:
a step of laminating a first multilayer film reflector and a resonator including an active layer in this order on a substrate; and
a step of forming a structure including a second multilayer film reflector on the resonator,
in which, in the step of forming the structure, a field effect transistor having a drain region at a position corresponding to a predetermined region of the active layer and having a source region at a position corresponding to a periphery of the predetermined region is formed.

(22) The method for manufacturing the surface emitting laser element according to (21),
in which the step of forming the structure includes:
a step of laminating a second multilayer film reflector on the resonator; and
a step of forming the drain region and the source region by implanting ions into the second multilayer film reflector.

(23) The method for manufacturing the surface emitting laser element according to (21),
in which the step of forming the structure includes:
a step of laminating a second multilayer film reflector, and a semiconductor layer having a conductivity type different from a conductivity type of the drain region and the source region in this order on the resonator;
a step of diffusing impurities into a region corresponding to the predetermined region of the semiconductor layer to form the drain region; and
a step of diffusing impurities into a region corresponding to a periphery of the predetermined region of the semiconductor layer to form the source region.

(24) The method for manufacturing the surface emitting laser element according to (21),
in which the step of forming the structure includes:
a step of laminating a semiconductor layer on the resonator;
a step of forming the drain region and the source region by implanting ions into the semiconductor layer;
a step of laminating a transparent conductive film on the semiconductor layer; and
a step of laminating the second multilayer film reflector on the transparent conductive film.

(25) The method for manufacturing the surface emitting laser element according to (21),
in which the step of forming the structure includes:
a step of laminating a semiconductor layer having a conductivity type different from a conductivity type of the drain region and the source region on the resonator;
a step of diffusing impurities into a region corresponding to the predetermined region of the semiconductor layer to form the drain region;
a step of diffusing impurities into a region corresponding to a periphery of the predetermined region of the semiconductor layer to form the source region;
a step of laminating a transparent conductive film on the semiconductor layer; and
a step of laminating the second multilayer film reflector on the transparent conductive film.

(26) The method for manufacturing the surface emitting laser element according to (21),
in which the step of forming the structure includes:
a step of laminating a second multilayer film reflector on the resonator;
a step of forming the drain region by removing a region of the second multilayer film reflector corresponding to a periphery of the predetermined region by etching;
a step of laminating a semiconductor layer having a conductivity type different from a conductivity type of a drain region and a source region on a region of the resonator from which the second multilayer film reflector has been removed; and
a step of diffusing impurities into the semiconductor layer to form the source region.

(27) A surface emitting laser array including a plurality of the surface emitting laser element according to any one of (1) to (19).

(28) An electronic device including the surface emitting laser element according to any one of (1) to (19).

(29) An electronic device including the surface emitting laser array according to (27).

(30) An electronic device including the light source device according to (20).

### REFERENCE SIGNS LIST

Light source device 1
10, 10-1 to 10-8, 20, 20-1 to 20-10, 30, 30-1, 30-2 Surface emitting laser element
101 First multilayer film reflector
103 Active layer
105, 205 Second multilayer film reflector
106, 206, 306 Semiconductor layer
106D, 206D, 105D Drain region
106S, 206S Source region
106n, 306n n-type semiconductor region
107, 207, 307 Second electrode (source electrode)
108, 208 Gate insulating film
109, 209 Gate electrode
110 First electrode (drain electrode)
ST1 First structure
ST2 Second structure
R Resonator
LA Light emitting region
IIA Ion implantation region (carrier confinement portion)
IIA1 First ion implantation region (carrier confinement portion)
IIA2 Second ion implantation region (ion implantation region)
1000 Distance measuring device

1. A surface emitting laser element comprising:
a first structure including a first multilayer film reflector;
a second structure including a second multilayer film reflector; and
a resonator disposed between the first and second structures,
wherein the resonator includes an active layer in which at least a light emitting region is disposed between the first and second multilayer film reflectors, and
the second structure is provided with a field effect transistor that controls injection of a current into the light emitting region.

2. The surface emitting laser element according to claim 1,
wherein the field effect transistor includes:
a drain region provided at a position of the second structure corresponding to the light emitting region; and
a source region of the second structure provided around the drain region.

3. The surface emitting laser element according to claim 2, wherein an electrical resistance between the source region and the first multilayer film reflector is larger than an electrical resistance between the drain region and the first multilayer film reflector.

4. The surface emitting laser element according to claim 2, wherein the source region surrounds the drain region.

5. The surface emitting laser element according to claim 2,
wherein the field effect transistor includes:
a gate electrode provided at a position of the second structure corresponding to the drain region and the source region; and
a gate insulating film provided between the gate electrode and the drain region and the source region.

6. The surface emitting laser element according to claim 2,
wherein the field effect transistor includes:
a source electrode provided at a position of the second structure in contact with the source region; and
a drain electrode provided in the first structure.

7. The surface emitting laser element according to claim 2, wherein the drain region and the source region are provided at a position of the second structure on a side opposite to a side of the active layer of the second multilayer film reflector.

8. The surface emitting laser element according to claim 7,
wherein the second structure further includes a semiconductor layer disposed on a surface of the second multilayer film reflector on a side opposite to the side of the active layer, and
the semiconductor layer includes:
a first impurity region as the drain region;
a second impurity region as the source region; and
a semiconductor region having a conductivity type different from a conductivity type of the drain region and the source region, at least a part of the semiconductor region being disposed between the first and second impurity regions.

9. The surface emitting laser element according to claim 8, wherein the drain region is in contact with the second multilayer film reflector, and
the source region is not in contact with the second multilayer film reflector.

10. The surface emitting laser element according to claim 2, wherein at least the drain region of the drain region and the source region is provided in the second multilayer film reflector.

11. The surface emitting laser element according to claim 10, wherein the drain region and the source region are provided in the second multilayer film reflector, and
an ion implantation region is provided between the drain region and the source region in the second multilayer film reflector.

12. The surface emitting laser element according to claim 11, wherein the ion implantation region is provided in an entire region in a thickness direction of the second multilayer film reflector.

13. The surface emitting laser element according to claim 2, wherein the second structure further includes a semiconductor layer disposed between the second multilayer film reflector and the resonator,
the drain region is a region corresponding to the light emitting region of the semiconductor layer, and
the source region is a region around the drain region of the semiconductor layer.

14. The surface emitting laser element according to claim 13, wherein an ion implantation region is provided between the drain region and the source region in the semiconductor layer.

15. The surface emitting laser element according to claim 14, wherein the ion implantation region is provided in an entire region in a thickness direction of the semiconductor layer.

16. The surface emitting laser element according to claim 13,
wherein the semiconductor layer includes:
a first impurity region as the drain region;
a second impurity region as the source region; and
a semiconductor region having a conductivity type different from a conductivity type of the drain region and the source region, at least a part of the semiconductor region being disposed between the first and second impurity regions.

17. The surface emitting laser element according to claim 13, wherein the second structure further includes a transparent conductive film in which a part corresponding to the light emitting region is disposed between the second multilayer film reflector and the semiconductor layer and an other part is exposed.

18. The surface emitting laser element according to claim 2,
wherein the second structure further includes a semiconductor layer disposed on a side opposite to a side of the first multilayer film reflector of the resonator and around the second multilayer film reflector,
the drain region is at least a part of the second multilayer film reflector, and
the semiconductor layer includes:
an impurity region as the source region; and
a semiconductor region having a conductivity type different from a conductivity type of the drain region and the source region, at least a part of the semiconductor region being disposed between the source region and the drain region.

19. The surface emitting laser element according to claim 1, wherein at least one of the resonator, the first multilayer film reflector, or the second multilayer film reflector is provided with a carrier confinement portion.

20. A light source device comprising:
a surface emitting laser element according to claim 1;
a first power supply that generates a current to be injected into a light emitting region of the surface emitting laser element; and
a second power supply that drives a field effect transistor of the surface emitting laser element.
